(19) United States
(12) Patent Application Publication
(10) Pub. No.: US 2025/0112151 A1
(43) Pub. Date: Apr. 3, 2025

(54) MICROELECTRONIC DEVICE WITH THICK CONDUCTIVE STAIRCASED STEPS FOR 3D DRAM, AND RELATED SYSTEMS AND METHODS OF FORMATION

(71) Applicant: Micron Technology, Inc., Boise, ID (US)

(72) Inventors: Si-Woo Lee, Saratoga, CA (US); Scott E. Sills, Boise, ID (US); Yuichi Yokoyama, Boise, ID (US)

(21) Appl. No.: 18/781,810

(22) Filed: Jul. 23, 2024

Related U.S. Application Data
(60) Provisional application No. 63/586,797, filed on Sep. 29, 2023.

(51) Int. Cl. H01L 23/528; H01L 23/532; H10B 12/00

(52) U.S. Cl. CPC H01L 23/5283; H01L 23/5329; H10B 12/30

(57) ABSTRACT

A microelectronic device includes a stack structure with tiers individually extending through an array area and into a staircase area horizontally neighboring the array area. The array area includes at least one access device. The staircase area includes a staircase structure having steps at ends of the tiers. At least some of the tiers individually include a conductive region, insulative regions, and discrete regions of semiconductor material. The conductive region includes conductive material extending through the array area and into the staircase area. The insulative regions are in both the array area and the staircase area. The discrete regions of semiconductor material are in the array area. The staircase area is substantially free of the semiconductor material. The conductive material is thicker in the staircase area than in the array area. Related electronic systems and methods of formation are also disclosed.

### CROSS-REFERENCE TO RELATED APPLICATION

This application claims the benefit, under 35 U.S.C. § 119 (e), of U.S. Provisional Patent Application Ser. No. 63/586,797, filed Sep. 29, 2023, the disclosure of which is hereby incorporated in its entirety herein by this reference.

### TECHNICAL FIELD

The disclosure, in various embodiments, relates generally to the field of microelectronic device design and fabrication. More specifically, the disclosure relates to methods of forming microelectronic devices of a 3D DRAM architecture including steps in a staircase area, and to related methods of formation and systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

Designing and fabricating three-dimensional DRAM devices (3D DRAM devices) continues to present challenges. Some such challenges arise from fabricating structures to include relatively thin material regions so as to maximize the number of regions within a given area (e.g., for maximum device scaling), while the thin material regions provide relatively narrow margins for accurate and reliable fabrication.

### BRIEF DESCRIPTION OF THE DRAWINGS

FIG. 1A is a schematic, cross-sectional, isometric view of a microelectronic device structure, according to embodiments of the disclosure.

FIG. 1B is an enlarged, along-X-axis view, of a portion of the structure of FIG. 1A, according to embodiments of the disclosure.

FIG. 2 through FIG. 18 are schematic, cross-sectional views of various processing stages of a method of forming a microelectronic device, such as including the microelectronic device structure(s) of FIG. 1A and FIG. 1B, according to embodiments of the disclosure, wherein FIG. 1A and FIG. 1B illustrate a stage following that of FIG. 18. Throughout FIG. 2 to FIG. 18, figures sharing the same numerical identifier may illustrate a same processing stage.

FIG. 19 is a schematic, cross-sectional, isometric view of a microelectronic device structure, according to embodiments of the disclosure, and FIG. 19 may also illustrate a stage of processing—in a method of fabrication—following the stage of FIG. 1A.

FIG. 20 is a block diagram of an electronic system, in accordance with embodiments of the disclosure.

FIG. 21 is a block diagram of a processor-based system, in accordance with embodiments of the disclosure.

### DETAILED DESCRIPTION

Structures (e.g., microelectronic device structures), apparatus (e.g., microelectronic devices), and systems (e.g., electronic systems), according to embodiments of the disclosure, include memory devices, which may be configured with three-dimensional DRAM (“3D DRAM”) architecture. The structures include array areas (e.g., which may include vertical strings of horizontally-oriented access devices) and horizontally adjacent staircase areas. The array and staircase areas are formed in a stack of interleaved materials formed in tiers. In the array area, the material stack includes semiconductor, conductive, and insulative materials. In the staircase area, the material stack includes conductive and insulative materials, and may be substantially free of semiconductor materials. In each of at least some of the tiers, the conductive material of the staircase area is continuous with the conductive material of the array area. Conductive regions in the staircase area are significantly thicker than conductive regions in the array area, which array area conductive regions are above and below discrete semiconductor regions. The conductive regions in the staircase area provide steps, and the relatively greater thickness of the conductive regions provides a greater processing margin for subsequent formation of other features, such as conductive contact structures, than if the steps were formed with a same relative thinness as the conductive regions above discrete semiconductor regions in the array area. Moreover, providing the material stack of the staircase area to have conductive and insulative materials, substantially without semiconductor material, may lessen the complexity of material-removal (e.g., etching) processes—useful for forming the steps of staircases—than if, e.g., semiconductor materials were also interleaved as in the array area. Accordingly, both the array areas and the staircase areas may be accurately and reliably fabricated.

As used herein, the terms “opening,” “trench,” “slit,” and “recess” mean and include a volume extending through or into at least one structure or at least one material, leaving a gap in that at least one structure or at least one material, or a volume extending between structures or materials, leaving a gap between the structures or materials. Unless otherwise described, an “opening,” “trench,” “slit,” and/or “recess” is not necessarily empty of matter and is not necessarily void space. An “opening,” “trench,” “slit,” or “recess” formed in or between structures or materials may comprise structure(s) or material(s) other than that in or between which the opening is formed. And, structure(s) or material(s) “exposed” within an opening, trench, slit, or recess is/are not necessarily in contact with an atmosphere or non-solid environment. Structure(s) or material(s) “exposed” within an opening, trench, slit, or recess may be adjacent or in contact with other structure(s) or material(s) that is/are disposed within the opening, trench, slit, or recess.

As used herein, the terms “substrate” and “base structure” mean and include a base material or other construction upon which components, such as tiered stacks and structures therein, are formed. The substrate or base structure may be a semiconductor substrate, a base semiconductor material on a supporting structure, a metal electrode, or a semiconductor substrate having one or more materials, structures, or regions formed thereon. The substrate may be a conventional silicon substrate or other bulk substrate including a semiconductive material. As used herein, the term “bulk substrate” means and includes not only silicon wafers, but also silicon-on-insulator (“SOI”) substrates, such as silicon-on-sapphire (“SOS”) substrates or silicon-on-glass (“SOG”) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. Furthermore, when reference is made to a “substrate” or “base structure” in the following description, previous process stages may have been utilized to form materials, structures, or junctions in the base semiconductor structure, base structure, or other foundation.

As used herein, the terms “insulative” and “insulating,” when used in reference to a material or structure, means and includes a material or structure that is electrically insulative or electrically insulating. An “insulative” or “insulating” material or structure may be formed of and include one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric carboxynitride material (e.g., a silicon carboxynitride (SiOₓC_{z}N_{y})), and/or air. Formulae including one or more of “x,” “y,” and/or “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and/or “z” atoms of an additional element (if any), respectively, for every one atom of another element (e.g., Si, Al, Hf, Nb, Ti). As the formulae are representative of relative atomic ratios and not strict chemical structure, an insulative material or insulative structure may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative” or “insulating” structure means and includes a structure formed of and including “insulative” or “insulating” material.

As used herein, the terms “conductive” and “conducting,” when used in reference to a material or structure, mean and include a material or structure that is electrically conductive or electrically conducting, unless otherwise specified (e.g., as “thermally conductive” or “thermally conducting”). A “conductive” or “conducting” material or structure may be formed of and include one or more metals or metal-containing compositions. The one or more metals or metal-containing compositions may be in the form of a single homogeneous material region, in the form of multiple material regions (e.g., as one material region at least partially lined by a second material region (e.g., liner)). The metals may include one or more of, e.g., tungsten (W), titanium, (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or aluminum (Al). Metal-containing compositions may include one or more alloys, nitrides, silicides, carbides, and/or oxides of and include any of the foregoing metals (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), such as a material including one or more of titanium nitride (TiN), tantalum nitride (TaN), tungsten nitride (WN), titanium aluminum nitride (TiAlN), iridium oxide (IrOₓ), ruthenium oxide (RuOₓ), and/or alloys thereof. A “conductive” or “conducting” material or structure may be formed of and include one or more of conductive metal-containing material(s) (e.g., a conductive metal nitride, a conductive metal silicide, a conductive metal carbide, a conductive metal oxide); conductively-doped semiconductor material(s) (e.g., conductively-doped polysilicon, conductively-doped germanium (Ge), conductively-doped germanium (Ge), conductively-doped silicon germanium (SiGe)); and/or combinations of any of the foregoing. In addition, a “conductive structure” means and includes a structure formed of and including a conductive material.

As used herein, the terms “semiconductor material” and “semiconductive material” mean and include a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnxSnyO, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, a “semiconductor” or “semiconductive” structure means and includes a structure formed of and including “semiconductor” or “semiconductive” material.

As used herein, the term “sacrificial,” when used in reference to a material or structure, means and includes a material or structure that is formed during a fabrication process but which is substantially removed (e.g., at least 50%, 60%, 70%, 80%, or 90% removed, wholly removed) prior to completion of the fabrication process.

As used herein, the term “horizontal” means and includes a direction that is parallel to a primary surface of the substrate on which the referenced material or structure is located. The “width” and “length” of a respective material or structure may be defined as dimensions in a horizontal plane. With reference to the figures, the “horizontal” direction may be perpendicular to an indicated “Z” axis, may be parallel to an indicated “X” axis, and may be parallel to an indicated “Y” axis.

As used herein, the term “lateral” means and includes a direction in a horizontal plane parallel to a primary surface of the substrate on which a referenced material or structure is located and substantially perpendicular to a “longitudinal” direction. The “width” of a respective material or structure may be defined as a dimension in the lateral direction of the horizontal plane. With reference to the figures, the “lateral” direction may be parallel to an indicated “Y” axis, may be perpendicular to an indicated “X” axis, and may be perpendicular to an indicated “Z” axis.

As used herein, the term “longitudinal” means and includes a direction in a horizontal plane parallel to a primary surface of the substrate on which a referenced material or structure is located, and substantially perpendicular to a “lateral” direction. The “length” of a respective material or structure may be defined as a dimension in the longitudinal direction of the horizontal plane. With reference to the figures, the “longitudinal” direction may be parallel to an indicated “X” axis, may be perpendicular to an indicated “Y” axis, and may be perpendicular to an indicated “Z” axis.

As used herein, the term “vertical” means and includes a direction that is perpendicular to a primary surface of the substrate on which a referenced material or structure is located. The “height” of a respective material or structure may be defined as a dimension in a vertical plane. With reference to the figures, the “vertical” direction may be parallel to an indicated “Z” axis, may be perpendicular to an indicated “X” axis, and may be perpendicular to an indicated “Y” axis.

As used herein, the term “width” means and includes a dimension, along an indicated “Y” axis in a horizontal plane (e.g., at a certain elevation, if identified), defining a maximum distance, along such “Y” axis in the horizontal plane, of the whole of the material or structure in question or of a concerned portion of the material or structure in question, which may or may not be a continuous, uninterrupted portion of the material or structure.

As used herein, the term “length” means and includes a dimension, along an indicated “X” axis in a horizontal plane (e.g., at a certain elevation, if identified), defining a maximum distance, along such “X” axis in the horizontal plane, of the whole of the material or structure in question or of a concerned portion of the material or structure in question, which may or may not be a continuous, uninterrupted portion of the material or structure.

As used herein, the terms “thickness” or “thinness” are spatially relative terms that mean and include a dimension in a straight-line direction that is normal to the closest surface of an immediately adjacent material or structure that is of a different composition or that is otherwise distinguishable from the material or structure whose thickness, thinness, or height is discussed. For structures and materials having primary and secondary dimensions defined in a horizontal plane, the “thickness” or “thickness” of such structure and material may be defined in a vertical plane.

As used herein, the term “between” is a spatially relative term used to describe the relative disposition of one material or structure relative to at least two other materials or structures. The term “between” may encompass both a disposition of one material or structure directly adjacent the other materials or structures and a disposition of one material or structure indirectly adjacent to the other materials or structures.

As used herein, the term “proximate” is a spatially relative term used to describe disposition of one material or structure near to another material or structure. The term “proximate” includes dispositions of indirectly adjacent to, directly adjacent to, and internal to.

As used herein, the term “neighboring,” when referring to a material or structure, means and refers to a next, most proximate material or structure of an identified composition or characteristic. One or more additional materials or structures of other compositions or characteristics than the identified composition or characteristic may be disposed between one material or structure and its “neighboring” material or structure of the identified composition or characteristic. For example, a structure of material X “neighboring” a structure of material “Y” is the first material X structure, e.g., of multiple material X structures, that is next most proximate to the particular structure of material Y. The “neighboring” material or structure may be directly or indirectly proximate the structure or material of the identified composition or characteristic. “Vertically neighboring” features include features of the disclosed identity that nearest one another along a vertical direction. “Horizontally neighboring” features include features of the disclosed identity that are nearest one another along a horizontal direction.

As used herein, the term “consistent”—when referring to a parameter, property, or condition of one structure, material, feature, or portion thereof in comparison to the parameter, property, or condition of another such structure, material, feature, or portion of such same aforementioned structure, material, or feature—is a relative term that means and includes the parameter, property, or condition of the two such structures, materials, features, or portions being equal, substantially equal, or about equal, at least in terms of respective dispositions of such structures, materials, features, or portions. For example, two structures having “consistent” thicknesses as one another may each define a same, substantially same, or about the same thickness, from a lower surface to an upper surface of each respective such structure, despite the two structures being at different elevations of a larger structure.

As used herein, the terms “about” and “approximately,” when either is used in reference to a numerical value for a particular parameter, are inclusive of the numerical value and a degree of variance from the numerical value that one of ordinary skill in the art would understand is within acceptable tolerances for the particular parameter. For example, “about” or “approximately,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0 percent met, at least 95.0 percent met, at least 99.0 percent met, or even at least 99.9 percent met.

As used herein, the terms “on” or “over,” when referring to an element as being “on” or “over” another element, are spatially relative terms that mean and include the element being directly on top of, adjacent to (e.g., laterally adjacent to, horizontally adjacent to, longitudinally adjacent to, vertically adjacent to), underneath, or in direct contact with the other element. It also includes the element being indirectly on top of, adjacent to (e.g., laterally adjacent to, horizontally adjacent to, longitudinally adjacent to, vertically adjacent to), underneath, or near the other element, with other elements present therebetween. In contrast, when an element is referred to as being “directly on” or “directly adjacent to” another element, there are no intervening elements present.

As used herein, other spatially relative terms, such as “below,” “lower,” “bottom,” “above,” “upper,” “top,” and the like, may be used for ease of description to describe one element's or feature's relationship to another element(s) or feature(s) as illustrated in the figures. Unless otherwise specified, any spatially relative terms used in this disclosure are intended to encompass different orientations of the materials in addition to the orientation as depicted in the figures. For example, if materials in the figures are inverted, elements described as “below” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (rotated ninety degrees, inverted, etc.) and the spatially relative descriptors used herein interpreted accordingly.

As used herein, the terms “level” and “elevation” are spatially relative terms used to describe one material's or feature's relationship to another material(s) or feature(s) as illustrated in the figures, using—as a reference point—the lowest illustrated surface of the structure that includes the materials or features. As used herein, a “level” and an “elevation” are each defined by a horizontal plane parallel to a primary surface of the substrate or base structure on or in which the structure (that includes the materials or features) is formed. When used with reference to the drawings, “lower levels” and “lower elevations” are relatively nearer to the bottom-most illustrated surface of the respective structure, while “higher levels” and “higher elevations” are relatively further from the bottom-most illustrated surface of the respective structure.

As used herein, the term “depth” is a spatially relative term used to describe one material's or feature's relationship to another material(s) or feature(s) as illustrated in the figures, using—as a reference point—the highest illustrated surface of the structure (e.g., stack structure) that includes the materials or features. When used with reference to the drawings, a “depth” is defined by a horizontal plane parallel to the highest illustrated surface of the structure (e.g., stack structure) that includes the materials or features.

Unless otherwise specified, any spatially relative terms used in this disclosure are intended to encompass different orientations in addition to the orientation as depicted in the drawings. For example, the materials in the drawings may be inverted, rotated, etc., with the “upper” levels and elevations then illustrated proximate the bottom of the page, the “lower” levels and elevations then illustrated proximate the top of the page, and the greatest “depths” extending a greatest vertical distance upward.

As used herein, the terms “comprising,” “including,” “having,” and grammatical equivalents thereof are inclusive, open-ended terms that do not exclude additional, unrecited elements or method steps. These terms also include more restrictive terms “consisting of” and “consisting essentially of” and grammatical equivalents thereof. Therefore, a structure described as “comprising,” “including,” and/or “having” a material may be a structure that, in some embodiments, includes additional material(s) as well and/or a structure that, in some embodiments, does not include any other material(s). Likewise, a material (e.g., composition) described as “comprising,” “including,” and/or “having” a species may be a material that, in some embodiments, includes additional species as well and/or a material that, in some embodiments, does not include any other species.

As used herein, the term “may” with respect to a material, structure, feature, or method act indicates that such is contemplated for use in implementation of an embodiment of the disclosure and such term is used in preference to the more restrictive term “is” so as to avoid any implication that other, compatible materials, structures, features, and methods usable in combination therewith should or must be excluded.

As used herein, “and/or” means and includes any and all combinations of one or more of the associated listed items.

As used herein, the singular forms “a,” “an,” and “the” are intended to include the plural forms as well, unless the context clearly indicates otherwise.

As used herein, an “(s)” at the end of a term means and includes the singular form of the term and/or the plural form of the term, unless the context clearly indicates otherwise.

As used herein, the terms “configured” and “configuration” mean and refer to a size, shape, material composition, orientation, and arrangement of a referenced feature (e.g., region, material, structure, opening, assembly, device) so as to facilitate a referenced operation or property of the referenced feature in a predetermined way.

The illustrations presented herein are not meant to be actual views of any particular material, structure, sub-structure, region, sub-region, device, system, or stage of fabrication, but are merely idealized representations that are employed to describe embodiments of the disclosure.

Embodiments are described herein with reference to cross-sectional illustrations that are schematic illustrations. Accordingly, variations from the shapes of the illustrations as a result, for example, of manufacturing techniques and/or tolerances, are to be expected. Thus, embodiments described herein are not to be construed as limited to the particular shapes or structures as illustrated but may include deviations in shapes that result, for example, from manufacturing techniques. For example, a structure illustrated or described as box-shaped may have rough and/or nonlinear features. Moreover, sharp angles that are illustrated may be rounded; surfaces and features illustrated to be vertical may be non-vertical, bent, and/or bowed; and/or structures illustrated with consistent transverse widths and/or lengths throughout the height of the structure may taper in transverse width and/or length. Thus, the materials, features, and structures illustrated in the figures are schematic in nature and their shapes are not intended to illustrate the precise shape of a material, feature, or structure and do not limit the scope of the present claims.

In the accompanying illustrations, figures accompanied by an X-Y-Z axes symbol are isometric views, figures accompanied by a Y-Z axes symbol are along-X-axis views, and figures accompanied by an X-Z axes symbol are along-Y-axis views.

The following description provides specific details, such as material types and processing conditions, to provide a thorough description of embodiments of the disclosed apparatus (e.g., devices, systems) and methods. However, a person of ordinary skill in the art will understand that the embodiments of the apparatus and methods may be practiced without employing these specific details. Indeed, the embodiments of the apparatus and methods may be practiced in conjunction with conventional semiconductor fabrication techniques employed in the industry.

The fabrication processes described herein do not form a complete process flow for processing apparatus (e.g., devices, systems) or the structures thereof. The remainder of the process flow is known to those of ordinary skill in the art. Accordingly, only the methods and structures necessary to understand embodiments of the present apparatus (e.g., devices, systems) and methods are described herein.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), plasma enhanced CVD (“PECVD”), low pressure CVD (“LPCVD”), or epitaxial growth. Additionally or alternatively, material(s) may be grown in situ. Depending on the specific material(s) to be formed, the technique for depositing or growing the material(s) may be selected by a person of ordinary skill in the art.

Unless the context indicates otherwise, the removal of materials described herein may be accomplished by any suitable technique including, but not limited to, etching (e.g., dry etching, wet etching, vapor etching), ion milling, abrasive planarization (e.g., chemical-mechanical planarization), or other known methods.

In referring to the drawings, like numerals refer to like components throughout. The drawings are not necessarily drawn to scale.

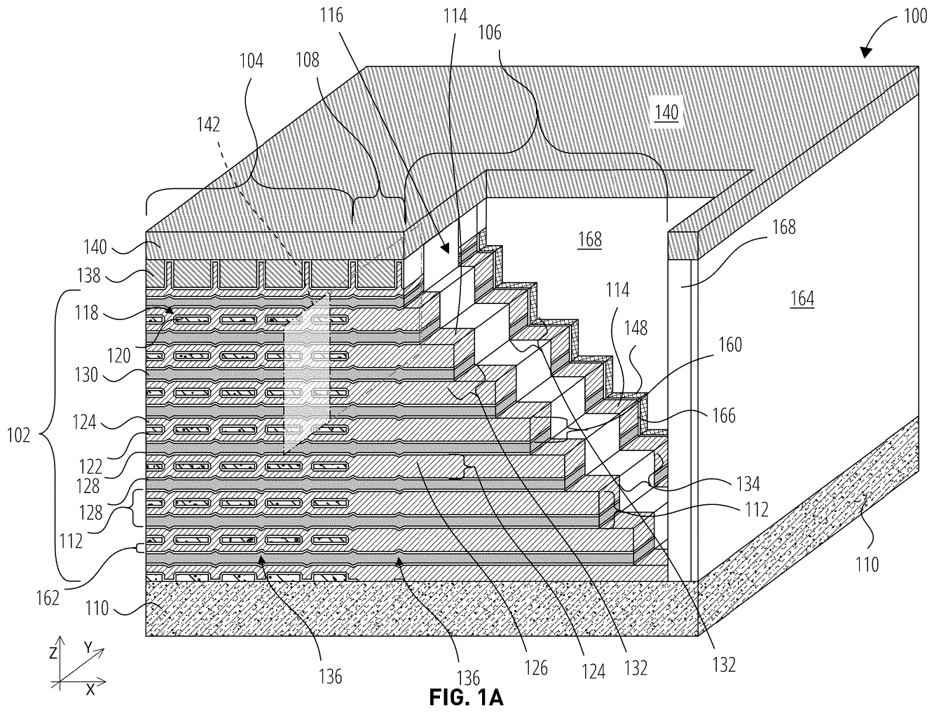

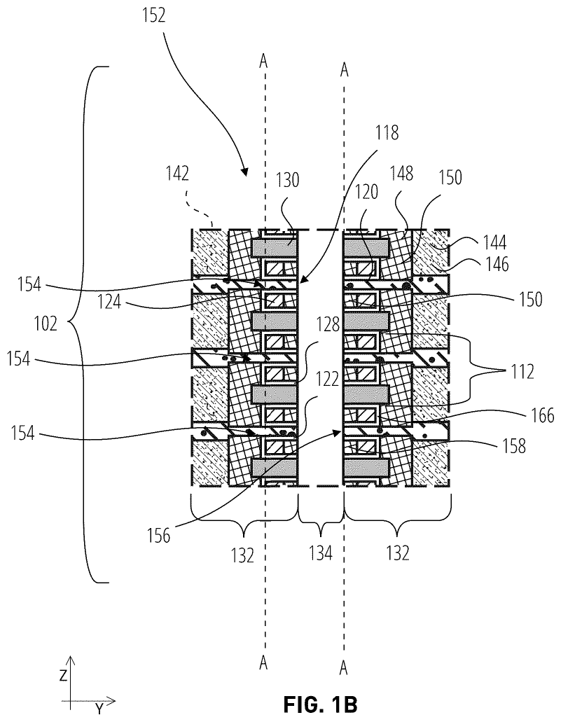

With reference to FIG. 1A, illustrated is a microelectronic device structure 100 that may be included, in whole or in part, in a microelectronic device and/or electronic system, according to embodiments of the disclosure. The microelectronic device structure 100 includes a vertical (e.g., in the Z-axis direction) stack structure 102 (which may otherwise be referred to herein as a “stack,” a “tiered stack,” and/or a “material stack”). Within the stack structure 102 are an array area 104 and a staircase area 106 of the microelectronic device structure 100. In some embodiments, a transition area 108 is horizontally interposed between the array area 104 and the staircase area 106. The stack structure 102 may be supported by a base structure 110.

Materials of the stack structure 102 are arranged in tiers 112. For at least some (e.g., a majority) of the height of the stack structure 102, each of the tiers 112 includes generally the same types of materials and structures along the height of the stack structure 102, except in the staircase area 106 where the tiers 112 may define steps 114 arranged in one or more staircase structures 116.

In the array area 104, the stack structure 102 includes vertically interleaved conductive, insulative, and semiconductor materials. A series of discrete regions 118 of semiconductor material 120 may be spaced along the length (e.g., X-axis dimension) of the array area 104. Surrounding each discrete region 118 (e.g., in the X-Z plane), one or more insulative material(s)—providing gate insulator regions 122 of access devices of the microelectronic device structure 100—space the semiconductor material 120 from a surrounding (e.g., in the X-Z plane) conductive region 124 formed of and including one or more conductive materials 126. The conductive regions 124 may provide gate electrode regions of the access device(s). Additional regions of the one or more insulative material(s)—which may be formed of the same or different insulative material(s) than the gate insulator region 122—may be included along at least upper and lower surfaces of the conductive region 124, providing outer insulative regions 128 above and below the conductive region 124. An intermediate insulative region 130—formed of one or more insulative material(s), which may be the same or different than the insulative material(s) of the gate insulator region 122 and/or the outer insulative regions 128—may be interposed between the uppermost outer insulative region 128 of one tier 112 and the lowermost outer insulative region 128 of a neighboring tier 112.

The semiconductor material 120 may be formed of and include, for example, a semiconductive material (e.g., silicon (Si)) or a semiconductor-based material (e.g., silicon dioxide). In some embodiments, the semiconductor material 120 comprises silicon, such as epitaxially grown silicon. In some embodiments, the semiconductor material 120 comprises monocrystalline silicon.

Accordingly, in the array area 104, each tier 112 includes the conductive material 126 (e.g., in the conductive region 124), insulative material (e.g., in the gate insulator region 122, in the outer insulative regions 128, and in the intermediate insulative region 130), and semiconductor material 120 (e.g., in the discrete regions 118). Above and below each discrete region 118 of semiconductor material 120 is an upper portion of the conductive region 124 and a lower portion of the conductive region 124, which upper and lower portions may be of generally about the same thickness as one another.

In the staircase area 106, the stack structure 102 includes vertically interleaved conductive and insulative materials. The stack structure 102 in the staircase area 106 may be substantially free of semiconductor materials (e.g., substantially free of the semiconductor material 120 (e.g., silicon)). More particularly, each tier 112 includes substantially the same material structure in the staircase area 106 as in the array area 104, but with the gate insulator region 122 and discrete region 118 of the semiconductor material 120 replaced with an additional amount of conductive material 126 to provide a relatively thicker conductive region 124 in the staircase area 106 compared to the upper and lower portions of the conductive region 124 in the array area 104. For example, the total thickness of the conductive material 126 in the conductive region 124 in the staircase area 106 may be at least twice as thick (e.g., about three times (3×) as thick) as the total thickness of conductive material 126 in the upper and lower portions of the conductive region 124 above and below the discrete regions 118 of semiconductor material 120 in the array area 104.

In addition to the relatively thick region of the conductive region 124 between upper and lower outer insulative regions 128, each tier 112 in the staircase area 106 also includes one of the intermediate insulative regions 130. Accordingly, in the staircase area 106, each tier 112 includes conductive material 126 (e.g., in the conductive region 124) and insulative material (e.g., in the outer insulative regions 128 and in the intermediate insulative region 130) but may be substantially free of semiconductor material (e.g., the semiconductor material 120). In the staircase area 106, the tiers 112 may also be substantially free of discrete material regions along the X-axis direction.

In the Y-axis direction, the stack structure 102 may be divided into blocks 132, and neighboring blocks 132 may be spaced from one another by an interblock insulative structure 134 formed of and including one or more insulative material(s). A series of the blocks 132 may be distributed along the Y-axis direction. The conductive regions 124 of the tiers 112 of one block 132 may be electrically isolated from longitudinally neighboring (Y-axis direction) conductive regions 124 of tiers 112 of neighboring blocks 132. In the staircase area 106, the conductive regions 124 may provide a longitudinally (Y-axis) distributed series of generally parallel access lines (e.g., word lines) that are in physical and electrical communication with arrays of access devices in the array area 104.

As described further below, the materials of the stack structure 102 may be formed so that the conductive region 124 extends—throughout each respective tier 112—substantially continuously throughout the portion of the tier 112 that is in the array area 104 and the portion of the tier that is in the staircase area 106. In the array area 104, upper boundaries and/or lower boundaries (e.g., surfaces) of the conductive region 124 may define divots 136 in areas laterally between neighboring discrete regions 118 of semiconductor material 120. The divots 136 may be a result of methods for forming the array area 104 of the stack structure 102, described further below. In the staircase area 106, the upper and/or lower surfaces of the conductive region 124 may be substantially planar and substantially free of divots 136.

In some embodiments, the stack structure 102 also includes a transition area 108 horizontally (e.g., laterally) between the array area 104 and the staircase area 106. The materials and tier 112 structure in the transition area 108 may be substantially the same as in the staircase area 106, except that the transition area 108 may also include divots 136 along upper and/or lower surfaces of the conductive region 124 at horizontally spaced increments along the length of the transition area 108.

In the staircase area 106, the conductive region 124 horizontally extends (e.g., in the X-direction) as lines and may horizontally terminate (e.g., in the X-direction) at steps 114 of the one or more staircase structures 116. The steps 114 include treads (each provided by an upper-faced surface area of the respective tier 112 where not overlapped by a higher-elevation tier 112). Each step 114 may expose a surface area at a distal (e.g., in the X-direction) end of one of the tiers 112. As described further below, each step 114 may provide a so-called “landing area” for a conductive contact for providing electrical communication between the conductive region 124 of the tier 112 (e.g., an access line, a word line of the tier 112) and other conductive features of the microelectronic device that includes the microelectronic device structure 100.

As described further below, the relatively thicker portion of conductive region 124 in the staircase area 106 may provide greater processing margins during certain fabrication stages—such as during patterning of the steps 114 and during formation of conductive contact structures—than if the same relative thinness of the upper and lower portions of the conductive region 124 in the array area 104 were included in the staircase area 106. Moreover, fabricating the stack structure 102 to include substantially only conductive material 126 (e.g., in the conductive region 124) and insulative material (e.g., in the outer insulative regions 128 and the intermediate insulative region 130), without including semiconductor material (e.g., the semiconductor material 120), may ease the complexity of material-removal techniques, such as may be used to patterning the steps 114 to form the staircase structures 116.

Though FIG. 1A illustrates a first mask material 138 and an upper material 140 above the stack structure 102, either or both of these materials may be sacrificial and may be wholly or partially removed prior to completion of fabrication of the device and/or system that includes the microelectronic device structure 100.

The array area 104 of the microelectronic device structure 100 may include vertical strings of horizontally-oriented access devices. For example, the area indicated by section plane 142 may be represented by the illustration of FIG. 1B, which is an enlarged, cross-sectional, along-X-axis view, according to at least some embodiments of the disclosure.

Blocks 132 on either side of the interblock insulative structure 134 may be of substantially mirrored structures, across the interblock insulative structure 134.

The stack structure 102 of one or more of the blocks 132 may include—along a sidewall that is distal from the sidewall nearest the interblock insulative structure 134—remnants 144 of first sacrificial material 146 vertically interleaved with relatively thicker regions of the semiconductor material 120 (compared to the thickness of the semiconductor material 120 in the discrete regions 118). Between this distal portion of the block 132 and a proximate portion (e.g., the portion near the interblock insulative structure 134 and that includes the interleaved conductive, insulative, and semiconductor material (e.g., the conductive region 124; the gate insulator region 122, the outer insulative region 128, and the intermediate insulative region 130; and the semiconductor material 120)), an intermediate portion may include remnants 148 of a second sacrificial material 150 vertically interleaved with relatively thinner regions of the semiconductor material 120 (relative to the regions of semiconductor material 120 in the distal portion).

In other embodiments, all of the sacrificial materials (e.g., the first sacrificial material 146, the second sacrificial material 150) are wholly removed during fabrication and are not be included in the blocks 132.

As illustrated in FIG. 1B, the gate insulator region 122 and the outer insulative region 128 may be provided by a single, continuous region (e.g., layer) of insulative material that substantially surrounds the upper, lower, and distal sidewall surfaces of each conductive region 124.

The array area 104 may be configured to provide a vertical stack 152 of horizontally-oriented access devices 154. The access devices 154 may include doped portions of the semiconductor material 120 forming channel regions 156 (e.g., in the discrete regions 118 of semiconductor material 120, vertically and laterally surrounded by the gate insulator regions 122). The channel region 156 may be doped with one or more of at least one N-type dopant, such as one or more of arsenic ions, phosphorous ions, and antimony ions. In other embodiments, the channel regions 156 are doped with at least one P type dopant, such as one or more of boron ions, aluminum ions, and gallium ions. In some embodiments, the channel regions 156 of the access devices 154 are horizontally between (e.g., in the X- and Y-directions) a source region and a drain region of the access devices 154. Accordingly, the access devices 154 may be “horizontally oriented.” The conductive region 124, in the array area 104 and vertically and laterally surrounding the discrete regions 118 of semiconductor material 120 (e.g., the channel regions 156), may function as an “all-around” or “ring” gate electrode of the access device 154, and the intervening gate insulator regions 122 may function as the “gate insulator” or “gate dielectric” of the access device 154.

Horizontally beside (e.g., in the Y-axis direction) the conductive region 124 and the intermediate insulative region 130 of each tier 112, a region of insulative (e.g., nitride) material—which may be a remnant 148 of a second sacrificial material 150 used during fabrication—may extend substantially the whole height of the conductive region 124, from lowermost surface of the lower portion to uppermost surface of the upper portion of the conductive region 124. In some embodiments, an additional region 158 of insulative material (e.g., nitride) is included between the conductive region 124 and the interblock insulative structure 134. The additional region 158 may have a same composition as the remnant 148 of second sacrificial material 150.

The access devices 154 vertically overlying (e.g., in the Z-axis direction) one another within one of the blocks 132 may be form the vertical stack 152 of horizontally-oriented access devices 154. The access device 154 of each tier 112 may be in electrical communication with an “access line” (e.g., a “word line”) provided by the portion of the conductive region 124 that is within the staircase area 106. The relatively greater thickness 160 (FIG. 1A) of the conductive region 124 in the conductive region 124—and, therefore, the relatively greater volume of conductive material 126 in the conductive region 124—may also enable the conductive region 124 of the access line (e.g., word line) to exhibit a lower electrical resistivity than if the conductive region 124 of the access line (e.g., word line) had the same lower thickness 162 and volume of conductive material 126 as in the array area 104.

Though FIG. 1A illustrates an upper material 140 above the stack structure 102 (and above the first mask material 138), in some embodiments, the upper material 140 is omitted (e.g., removed during fabrication). For example, the microelectronic device structure 100 illustrated in FIG. 1A may be an intermediary (e.g., not final) structure in a stage of fabricating a final microelectronic device structure, and the upper material 140 may be a resist or mask material.

In some embodiments, additional conductive structures are included above (e.g., in the Z-axis direction), horizontally adjacent (e.g., in the X-axis direction, in the Y-axis direction), or below (e.g., in or under the base structure 110). The additional conductive structures may be in functional operation with the access devices 154 and/or the access lines (e.g., the conductive regions 124 of the staircase area 106).

Accordingly, disclosed is a microelectronic device comprising a stack structure. The stack structure comprises tiers. Some or all of the tiers individually extend through an array area of the stack structure and into a staircase area of the stack structure. The staircase area horizontally neighbors (e.g., directly or indirectly) the array area. The array area comprises at least one access device. The staircase area comprises a staircase structure having steps at ends of the tiers (e.g., in portions of the tiers that are laterally distal from the array area). At least some of the tiers individually comprise a conductive region, insulative regions, and discrete regions of semiconductor material. The conductive region, of each of the at least some of the tiers, comprises conductive material extending through the array area and into the staircase area. A thickness of the conductive material—of individual conductive regions—is greater in the staircase area than in the array area. The insulative regions are in the array area and in the staircase area. The discrete regions of the semiconductor material are in the array area. The staircase area is substantially free of the semiconductor material.

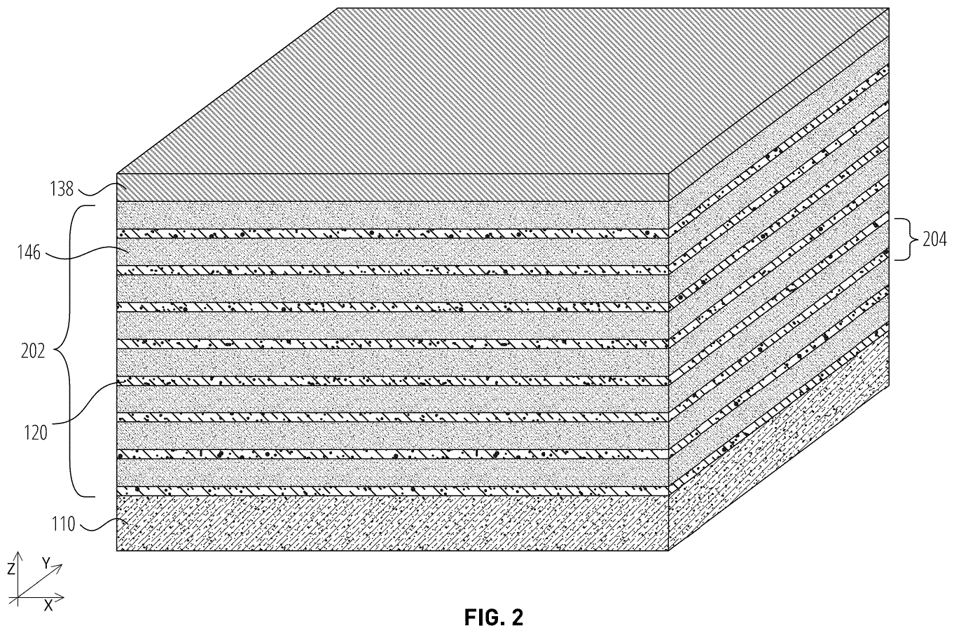

With reference to FIG. 2 through FIG. 18, illustrated are various processing stages of fabricating a microelectronic device and microelectronic device structure(s) thereof, such as the microelectronic device structure 100 of FIG. 1A and/or the access devices of FIG. 1B.

FIG. 2 is an isometric, cross-sectional, illustration of a precursor stack structure 202 formed on and supported by the base structure 110. The precursor stack structure 202 includes a vertical (e.g., in the Z-direction) material stack of vertically interleaved semiconductor material 120 and first sacrificial material 146.

The semiconductor material 120 may be formed of and include one or more semiconductive material(s), as described above.

The first sacrificial material 146 may have a different material composition than the semiconductor material 120 and may be selected or otherwise tailored to have etch selectivity with respect to the semiconductor material 120. The first sacrificial material 146 may be formed of and include one or more of silicon germanium (SiGe), polysilicon, a nitride material (e.g., silicon nitride (Si₃N₄)), or an oxynitride material (e.g., silicon oxynitride). In some embodiments, such as embodiments in which the semiconductor material 120 comprises silicon (Si), the first sacrificial material 146 comprises silicon germanium (SiGe) and/or polysilicon. In other embodiments, such as where the semiconductor material 120 comprises silicon dioxide, the first sacrificial material 146 comprises silicon nitride and/or silicon oxynitride.

The precursor stack structure 202 may be formed by alternating between forming (e.g., depositing or growing) the semiconductor material 120 and forming (e.g., depositing or growing) the first sacrificial material 146 through a height of the final stack structure 102 (FIG. 1A) to be formed. Thus, the precursor stack structure 202 may include a vertically alternating (e.g., in the Z-direction) sequence of the semiconductor material 120 and the first sacrificial material 146 arranged in precursor tiers 204.

Though FIG. 2 illustrates the regions of the first sacrificial material 146 to be thicker (e.g., of greater vertical, Z-axis dimension) than the regions of the semiconductor material 120, the disclosure is not so limited. In other embodiments, the regions of semiconductor material 120 are thicker than the regions of the first sacrificial material 146.

Though FIG. 2 illustrates each region of semiconductor material 120 as of generally equal thickness to one another and illustrates each region of the first sacrificial material 146 as of generally equal thickness to one another, the disclosure is not so limited. In some embodiments, some regions of semiconductor material 120 are thicker than other regions of semiconductor material 120, and/or some regions of the first sacrificial material 146 may be thicker than other regions of the first sacrificial material 146.

A first mask material 138 may be formed (e.g., deposited) above the precursor stack structure 202. In some embodiments, one or more other materials (e.g., a semiconductor material) are formed above the precursor stack structure 202 prior to forming the first mask material 138. Such intervening material(s) may be used for forming, e.g., control logic devices of the microelectronic device to facilitate control operations for memory cells of the device.

The first mask material 138 may be formed of and include one or more of a photoresist material, a nitride mask (e.g., silicon nitride, titanium nitride, aluminum nitride), a silicon oxide (e.g., silicon dioxide), or a combination of any of the foregoing. In some embodiments, the first mask material 138 includes a hard-mask material comprising, consisting essentially of, or consisting of silicon nitride and/or silicon dioxide. However, the disclosure is not so limited, and the first mask material 138 may include materials other than those described above. In some embodiments, the first mask material 138 is substantially free of carbon.

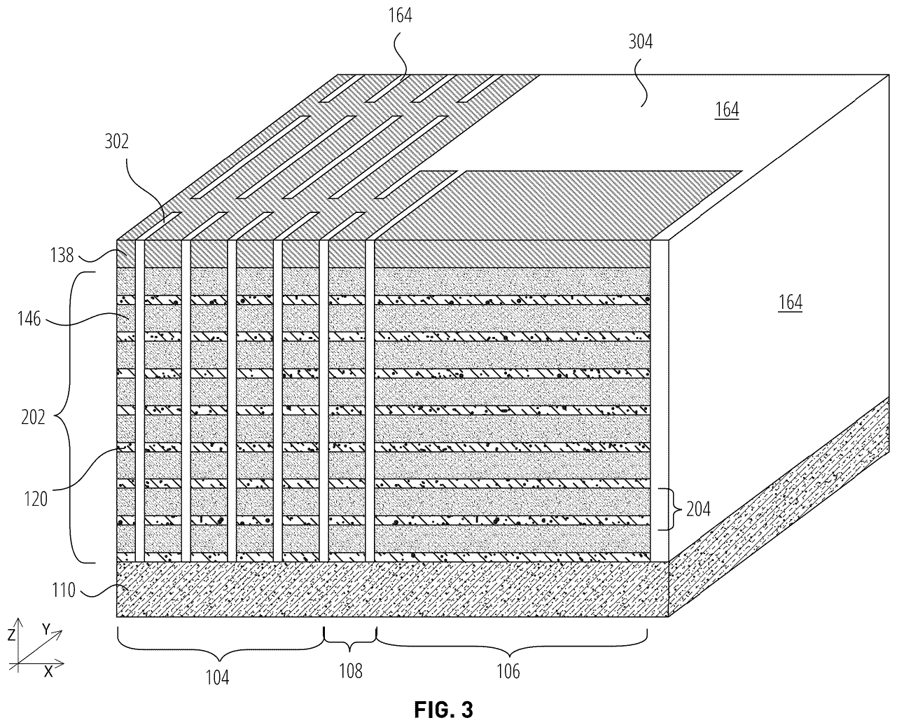

FIG. 3 is an isometric, cross-sectional, illustration of a processing stage subsequent to the processing stage illustrated in FIG. 2. Using the first mask material 138, isolation trenches and other isolation openings may be formed (e.g., etched) to vertically extend (e.g., in the Z-direction) through the precursor stack structure 202 to divide the precursor stack structure 202 into different areas from which features of the microelectronic device (e.g., features of the microelectronic device structure 100 of FIG. 1A and FIG. 1B) may be formed. One or more insulative material(s) (e.g., insulative material 164) may be formed (e.g., deposited) in the trenches to form trench isolation structures 302 in the array area 104 and, if included, the transition area 108. In some embodiments, the trench isolation structures 302 are so-called “deep trench isolation” (DTI) structures. The same or other insulative material(s) (e.g., insulative material 164) may be formed in other isolation openings to form one or more additional isolation areas 304, which may define an edge of the staircase area 106.

In some embodiments, the insulative material 164 of the trench isolation structures 302 and/or the additional isolation area 304 are formed of and include one or more materials that have etch selectivity with respect to at least the semiconductor material 120. By way of non-limiting example, in embodiments in which the semiconductor material 120 comprises silicon (Si) and the first sacrificial material 146 comprises silicon germanium (SiGe), the insulative material 164 may comprise one or more of silicon oxide, silicon oxycarbide, silicon boron nitride (SiBN), and/or silicon carbonitride (SiCN). In some such embodiments, the insulative material 164 comprises a spin-on-dielectric (SOD) material.

The trench isolation structure 302 may generally extend both vertically and longitudinally (e.g., in the Y-axis) direction, and along the longitudinal (Y-axis) direction, the trench isolation structures 302 may be spaced from one another by regions of un-patterned areas of the precursor stack structure 202 (and first mask material 138).

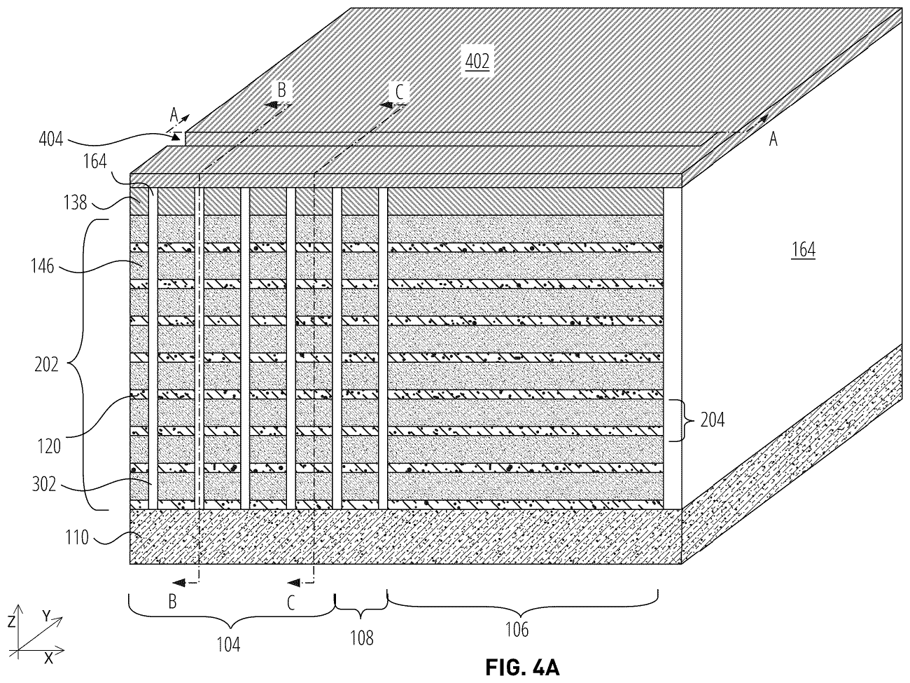

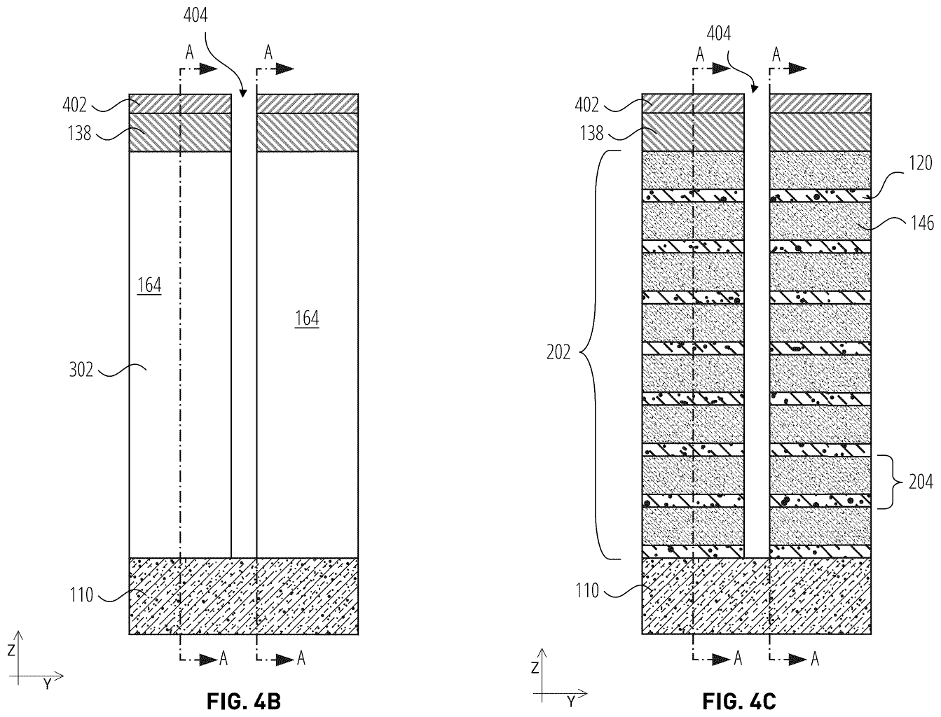

FIG. 4A, FIG. 4B, and FIG. 4C illustrate a processing stage subsequent to the processing stage illustrated in FIG. 3. FIG. 4A is an isometric, cross-sectional illustration. FIG. 4B is an along-X-axis view corresponding to section line B-B of FIG. 4A. FIG. 4C is an along-X-axis view corresponding to section line C-C of FIG. 4A. The front side of the illustration of FIG. 4A equally represents an along-Y-axis view that corresponds to either of section lines A-A of FIG. 4B and FIG. 4C. Though FIG. 4C is a cross-sectional view in the array area 104, it equally represents a cross-sectional view in either or both the staircase area 106 and/or the transition area 108.

A second mask material 402 may be formed (e.g., deposited) over the structure of FIG. 3, such as over the first mask material 138. In some embodiments, the second mask material 402 comprises substantially the same material composition as the first mask material 138. Accordingly, the first mask material 138 and the second mask material 402 may form a substantially indistinguishable, unitary mask region above the precursor stack structure 202.

One or more access line trenches 404 may be formed (e.g., etched) through the second mask material 402, the first mask material 138, and the precursor stack structure 202 in interblock area(s), which are areas between areas in which a pair of neighboring blocks 132 (FIG. 1B) are to be formed and across which the neighboring blocks 132 may mirror one another. Each such access line trench 404 may be formed in an individual generally unpatterned area longitudinally between ends of trench isolation structures 302 (see FIG. 3). In some embodiments, one access line trench 404 is formed for every pair of blocks 132 (FIG. 1A, FIG. 1B). The access line trenches 404 may be substantially parallel to one another and extend in the lateral (X-axis direction), substantially perpendicularly to the trench isolation structures 302.

As illustrated in FIG. 4B and FIG. 4C, respectively, the access line trenches 404 may be formed so that sidewalls bordering the access line trench 404 are provided primarily by the insulative material 164 of the trench isolation structures 302 and by the semiconductor material 120 and the first sacrificial material 146 of the precursor tiers 204 of the precursor stack structure 202. In some embodiments, the access line trench 404 may extend through an entire height of the precursor stack structure 202 and to and/or into the base structure 110.

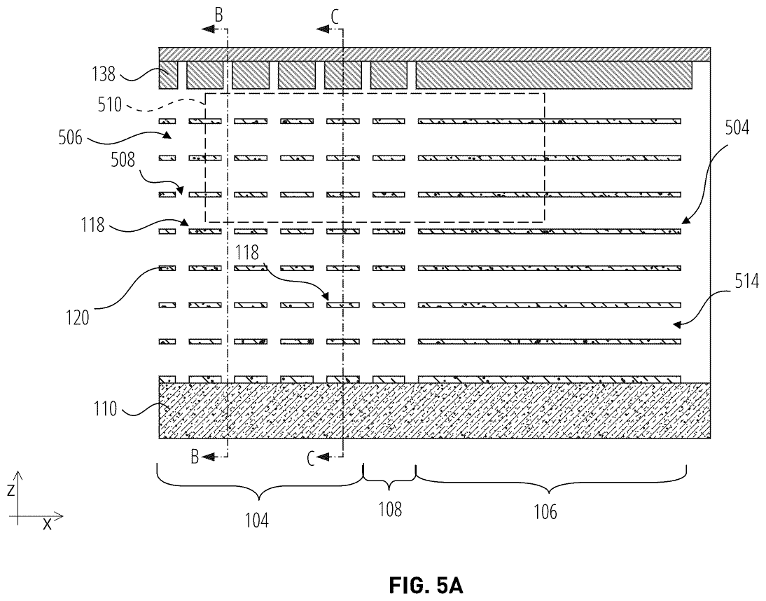

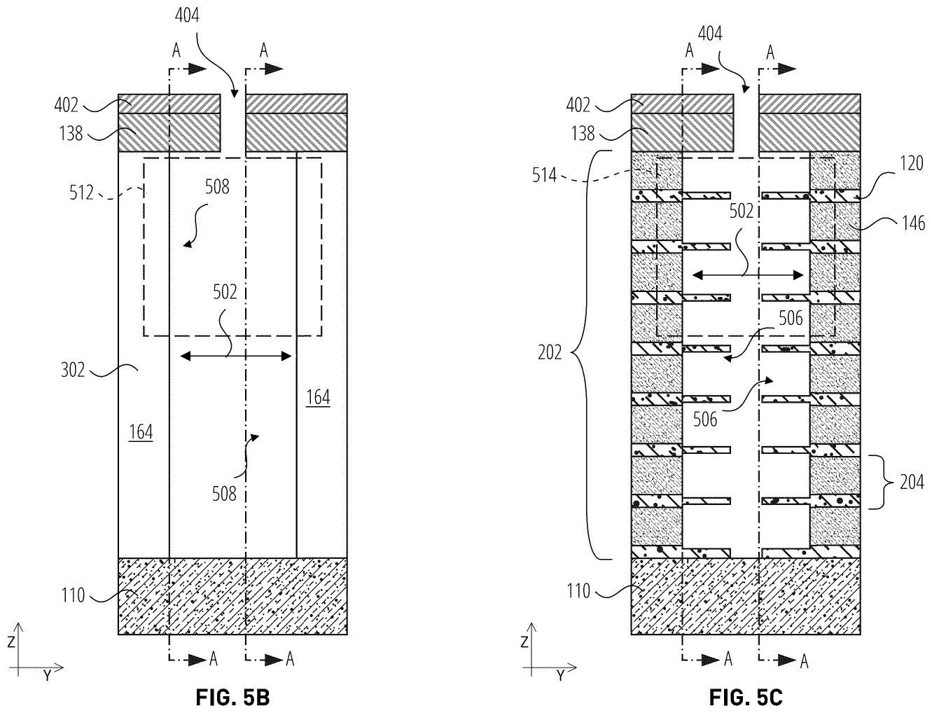

FIG. 5A, FIG. 5B, and FIG. 5C illustrate a processing stage subsequent to the processing stage illustrated in FIG. 4A, FIG. 4B, and FIG. 4C. FIG. 5A is a front, elevational, cross-sectional illustration. FIG. 5B is an along-X-axis view corresponding to section line B-B of FIG. 5A. FIG. 5C is an along-X-axis view corresponding to section line C-C of FIG. 5A. FIG. 5A equally represents an along-Y-axis view corresponding to either of section lines A-A of FIG. 5B and FIG. 5C. Though FIG. 5C is a cross-sectional view in the array area 104, it equally represents a cross-sectional view in either or both the staircase area 106 and/or the transition area 108. Though FIG. 5B is a cross-sectional view in the array area 104, it equally represents a cross-sectional view where the array area 104 meets the transition area 108 and/or where the transition area 108 meets the staircase area 106.

Via the access line trenches 404, portions of the first sacrificial material 146 and portions of the insulative material 164 of the trench isolation structures 302 nearest the access line trench 404 may be removed (e.g., horizontally recessed, such as by etching with selectivity relative to the semiconductor material 120), in one or more stages. In some embodiments, the semiconductor material 120 may be somewhat thinned near the access line trench 404 during or after the horizontal recessing of the first sacrificial material 146 and the insulative material 164. Horizontal recesses 502 may, therefore, be formed through the precursor stack structure 202 adjacent the (e.g., each) access line trench 404.

The horizontal recessing of the first sacrificial material 146 and the insulative material 164 may form the discrete regions 118 (FIG. 5A) of the semiconductor material 120, in the array area 104 and in the transition area 108, if included, and form elongate regions 504 of the semiconductor material 120 in the staircase area 106.

The discrete regions 118 and the elongate regions 504 of the semiconductor material 120 may be vertically surrounded (e.g., both above and below) by voids 506 in the space previously occupied by the first sacrificial material 146 (FIG. 5C). The discrete regions 118 may also be laterally surrounded (e.g., to both X-axis direction sides) by voids 508 in the space previously occupied by the insulative material 164 of the trench isolation structures 302 (FIG. 5B).

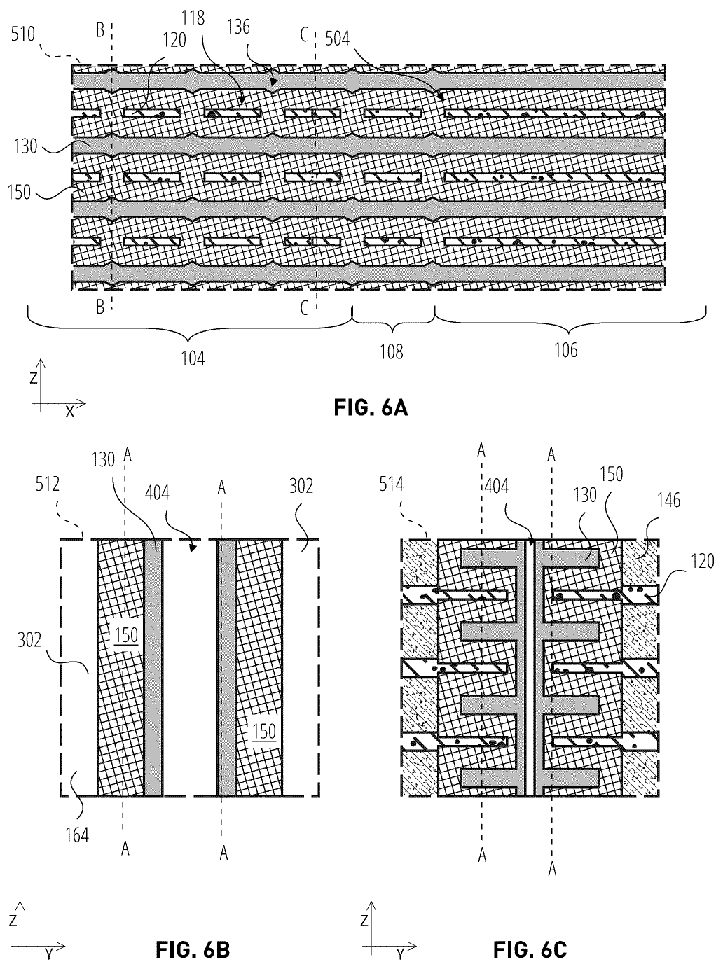

FIG. 6A, FIG. 6B, and FIG. 6C illustrate a processing stage subsequent to the processing stage illustrated in FIG. 5A, FIG. 5B, and FIG. 5C. FIG. 6A is a front (e.g., along-Y-axis), elevational, cross-sectional illustration of a portion of the microelectronic device structure corresponding to the area of box 510 of FIG. 5A. FIG. 6B is an along-X-axis view corresponding to section line B-B of FIG. 6A and also corresponding to the area of box 512 of FIG. 5B, though at a subsequent stage. FIG. 6C is an along-X-axis view corresponding to section line C-C of FIG. 6A and also corresponding to the area of box 514 of FIG. 5C, though at a subsequent stage. FIG. 6A equally illustrates an along-Y-axis view corresponding to either of section lines A-A of FIG. 6B and FIG. 6C. Though FIG. 6C is a cross-sectional view in the array area 104, it equally represents a cross-sectional view in either or both the staircase area 106 and/or the transition area 108. Though FIG. 6B is a cross-sectional view in the array area 104, it equally represents a cross-sectional view where the array area 104 meets the transition area 108 and/or where the transition area 108 meets the staircase area 106.

At least second sacrificial material 150 may be formed (e.g., conformally deposited) in the voids 506, 508 (FIG. 5A, FIG. 5B, FIG. 5C), to laterally and vertically surround the discrete regions 118 and the elongate regions 504 of the semiconductor material 120. This conformal formation of the second sacrificial material 150 may define the divots 136 in upper and lower surfaces in the array area 104 and in the transition area 108, if included. The second sacrificial material 150 may be formed on substantially all exposed surfaces, including on the recessed sidewalls of the insulative material 164 of the trench isolation structure 302, as illustrated in FIG. 6B, and the recessed sidewalls of the first sacrificial material 146, as illustrated in FIG. 6C.

After forming the second sacrificial material 150, the insulative material(s) of the intermediate insulative region 130 may then be formed (e.g., conformally deposited) on the second sacrificial material 150 to substantially fill remaining space of the voids 506, void 508 (FIG. 5A, FIG. 5B, FIG. 5C).

The intermediate insulative region 130 may be formed of and include one or more insulative material(s), which may be the same or different than insulative material(s) of other insulative regions described herein. In some embodiments, the intermediate insulative region 130 comprises, consists essentially of, or consists of an oxide material (e.g., silicon oxide). In some embodiments, the intermediate insulative region 130 comprises, consists essentially of, or consist of an oxycarbide material (e.g., silicon oxycarbide).

The composition of the second sacrificial material 150 may be formulated or otherwise configured to be selectively removable (e.g., etchable) relative to the insulative material(s) of the intermediate insulative region 130 and the semiconductor material 120 of the discrete regions 118 and the elongate regions 504. In some embodiments, the second sacrificial material 150 comprises a nitride material (e.g., silicon nitride (Si₃N₄)) or an oxynitride material (e.g., silicon oxynitride). In some embodiments, the second sacrificial material 150 comprises, consists essentially of, or consist of silicon nitride.

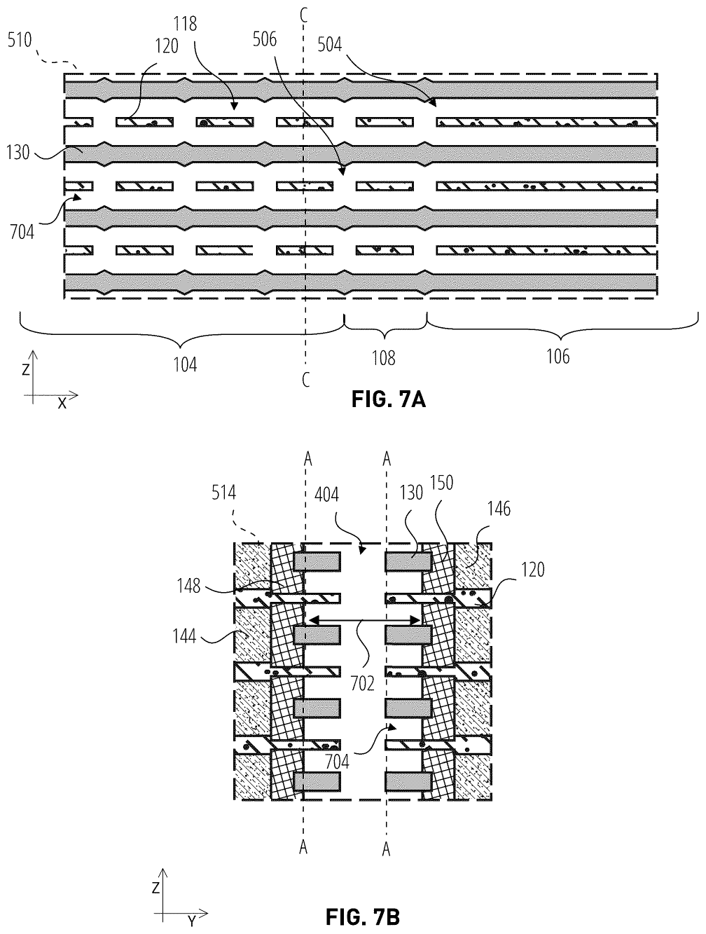

FIG. 7A and FIG. 7B illustrate a processing stage subsequent to the processing stage illustrated in FIG. 6A, FIG. 6B, and FIG. 6C. FIG. 7A is a front (e.g., along-Y-axis), elevational, cross-sectional illustration of the portion of the microelectronic device structure corresponding to the area of box 510 of FIG. 5A and FIG. 6A. FIG. 7B is an along-X-axis view corresponding to section line C-C of FIG. 7A and also corresponding to the area of box 514 of FIG. 5C and FIG. 6C, though at a subsequent stage. FIG. 7A equally illustrates an along-Y-axis view corresponding to either of section lines A-A of FIG. 7B. Though FIG. 7B is a cross-sectional view in the array area 104, it equally represents a cross-sectional view in either or both the staircase area 106 and/or the transition area 108.

After forming the intermediate insulative regions 130, the second sacrificial material 150 (FIG. 7B) may be partially removed, via the access line trenches 404, to form horizontal recesses 702, providing horizontal recesses 702, or otherwise referred to herein as voids 704. The partial removal of the second sacrificial material 150 may be by way of selective etching, relative to the intermediate insulative region 130 and the semiconductor material 120. Accordingly, the voids 704 may be vertically between the regions (e.g., discrete regions 118 and elongate regions 504 (FIG. 7A)) of the semiconductor material 120.

In some embodiments, some portions of the second sacrificial material 150 are not removed, forming remnants 148 as illustrated in FIG. 7B, that continue to support the intermediate insulative regions 130. Portions of the first sacrificial material 146 may also remain as remnants 144.

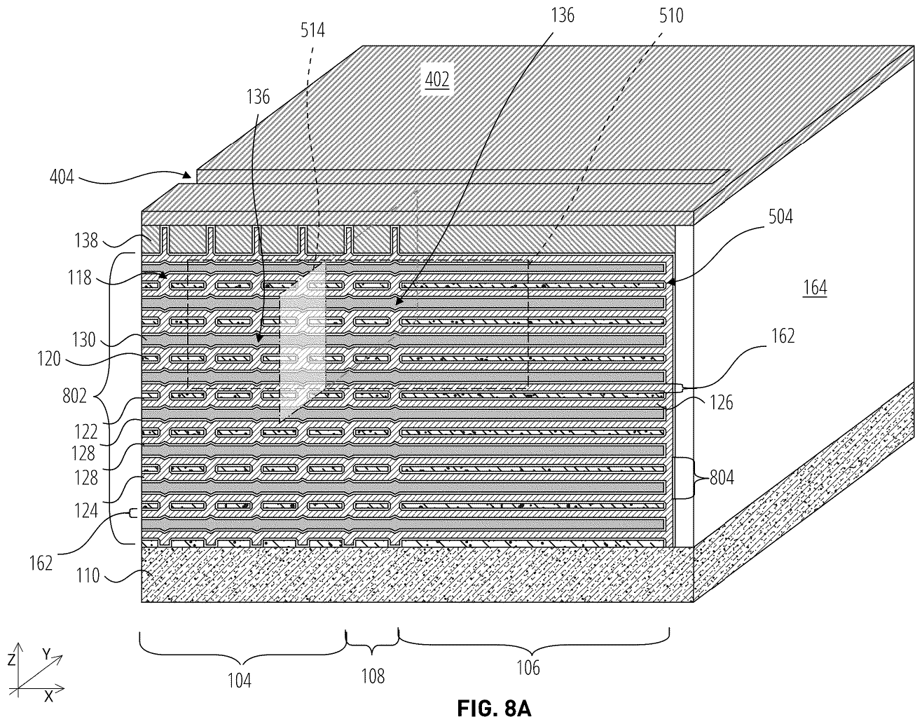

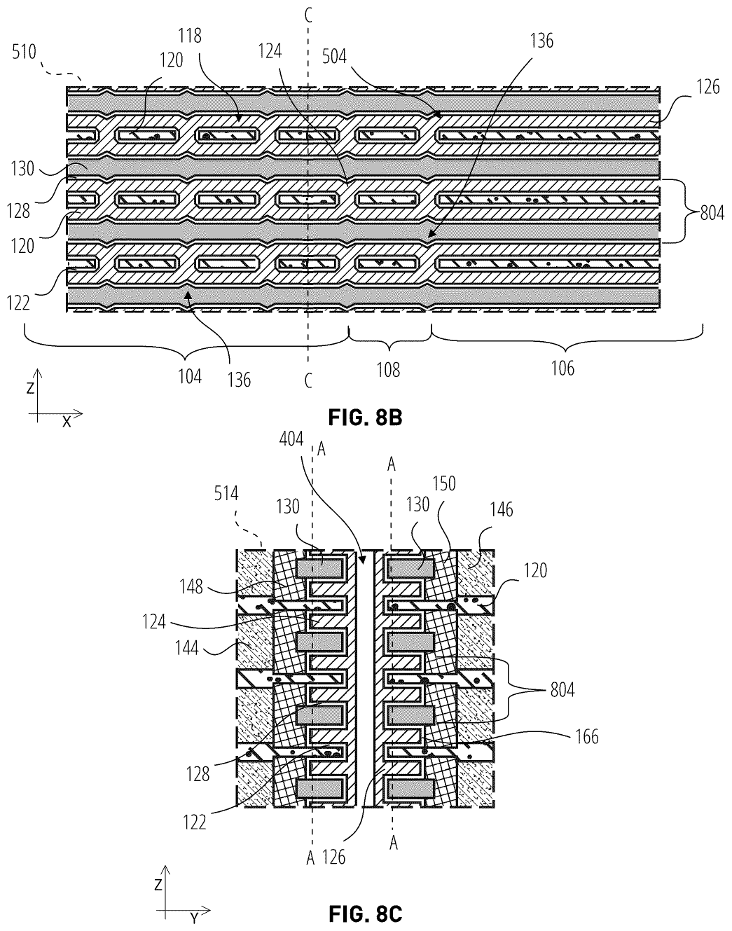

FIG. 8A, FIG. 8B, and FIG. 8C illustrate a processing stage subsequent to the processing stage illustrated in FIG. 7A and FIG. 7B. FIG. 8A is an isometric, cross-sectional illustration. FIG. 8B is a front (e.g., along-Y-axis), elevational, cross-sectional illustration of an area corresponding to box 510 of FIG. 8A and other figures. FIG. 8C is an along-X-axis view of an area corresponding to box 514 of FIG. 8A and other figures and corresponds to a view along section line C-C of FIG. 8B. Though FIG. 8C is a cross-sectional view in the array area 104, it equally represents a cross-sectional view in either or both the staircase area 106 and/or the transition area 108.

After horizontally recessing the second sacrificial material 150 (FIG. 7B), the insulative material(s) of the gate insulator regions 122 and the outer insulative regions 128 may be formed (e.g., conformally deposited) in the voids 704 (FIG. 7A and FIG. 7B). Accordingly, the insulative material(s) may be formed directly on exposed surfaces of the semiconductor material 120 to form the gate insulator regions 122, on exposed surfaces of the intermediate insulative regions 130 to form the outer insulative regions 128, and on exposed surfaces of the second sacrificial material 150 to form the insulative regions 166 (e.g., vertical sidewalls). In some embodiments, the insulative material(s) is formed as a material region that is substantially continuous between the gate insulator regions 122, the insulative regions 166, and the outer insulative regions 128.

The conductive material 126 of the conductive region 124 may then be formed (e.g., conformally deposited) in the access line trenches 404 on the insulative material(s) of the gate insulator regions 122, the insulative regions 166, and the outer insulative regions 128. At this stage, the conductive material 126 may provide a substantially continuous material region along each side and, optionally, along the base of the access line trench 404, as illustrated in FIG. 8C. The sidewall portions of the conductive material 126 may be removed (e.g., anisotropically etched) to reopen the access line trench 404 and to isolate the conductive material 126 into an individual conductive region 124 for each tier 112 (FIG. 1A) to be formed.

Accordingly, formed is an intermediary stack structure 802 (FIG. 8A) with—in each of the array area 104, the staircase area 106, and the transition area 108—a vertically repeating sequence of semiconductor material 120 (of the discrete regions 118 and elongate regions 504), insulative material(s) (of the gate insulator regions 122, outer insulative regions 128, and intermediate insulative regions 130), and conductive material 126 (of the conductive regions 124). For each intermediary tier 804, the conductive region 124 is provided by a substantially continuous region of the conductive material 126, and the conductive material 126 vertically and laterally surrounds the semiconductor material 120 of the row of discrete regions 118 in the array area 104 and the transition area 108 and the semiconductor material 120 of the elongate region 504 in the staircase area 106.

With continued reference to FIG. 8A, at this stage of the fabrication process, the conductive region 124 of the staircase area 106 exhibits substantially the same thickness 162 (FIG. 8A) as in the array area 104, with respect to the conductive material 126 that is vertically above the semiconductor material 120. In the array area 104, further fabrication stages may be performed to complete fabrication of vertical arrays of horizontally-oriented access devices, such as those illustrated in FIG. 1B, for which the relatively thin conductive region 124 vertically and horizontally surrounding the discrete regions 118 of semiconductor material 120 may form so-called “all-around” gate electrodes of the access devices. The interposed gate insulator regions 122 may provide so-called “gate oxide” regions of the access devices, in embodiments in which the insulative material thereof comprises an oxide (e.g., silicon oxide).

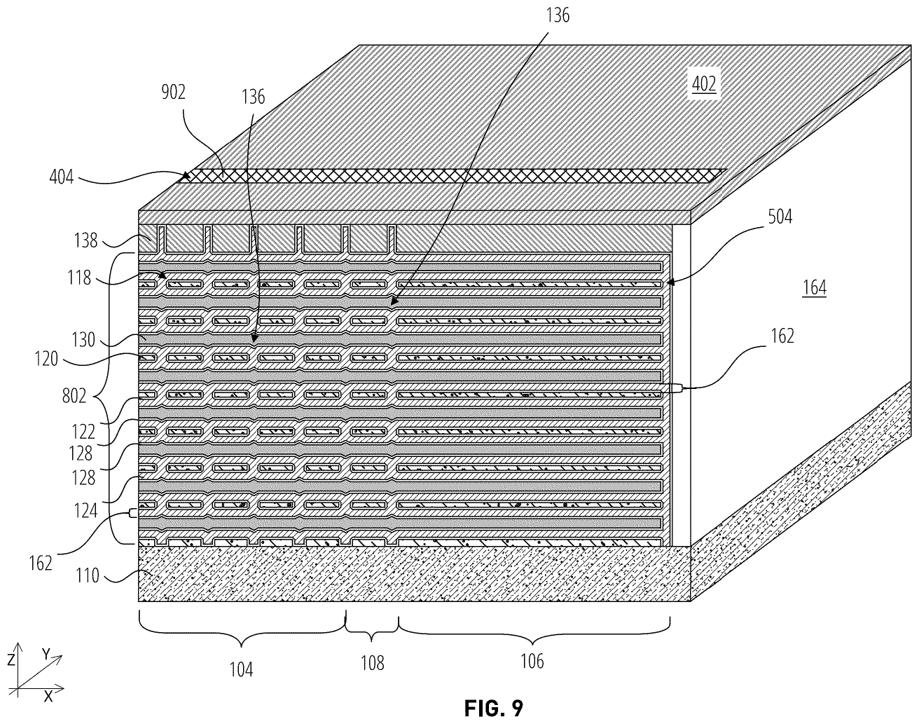

Though the relatively thin conductive region 124 in the array area 104 may be conducive for fabricating the vertical array of horizontally-oriented access devices, the low thickness 162 of the conductive material 126 and conductive region 124 in the staircase area 106, and the presence of the semiconductor material 120 in the staircase area 106, may present fabrication complexities if patterned at this stage to form the staircase structures 116 (FIG. 1A). For example, patterning through a stack (e.g., the intermediary stack structure 802) of conductive, insulative, and semiconductor material in the staircase area 106 may involve multiple different etching techniques, and etching to form steps 114 (FIG. 1A) at target areas of the conductive material 126 without inadvertently etching through the whole thickness 162 of the conductive material 126 may leave little margin for error. Accordingly, by embodiments of this disclosure, the semiconductor material 120 in the staircase area 106 and, optionally in the transition area 108, may be removed and replaced with additional conductive material 126 prior to patterning the staircase area 106, as described further below with regard to FIG. 9 through FIG. 18.

FIG. 9 illustrates a processing stage subsequent to the stage illustrated in FIG. 8A, FIG. 8B, and FIG. 8C. FIG. 9 is an isometric, cross-sectional illustration.

One or more third sacrificial materials 902 may be formed (e.g., deposited) in the access line trenches 404, including in the array area 104, the staircase area 106, and the transition area 108, if included.

The third sacrificial material 902 may be formed of and include a material formulated or otherwise configured to be selectively removable (e.g., etchable) relative to the materials of the intermediary stack structure 802. In some embodiments, the third sacrificial material 902 is also formulated or otherwise configured to be selectively removable (e.g., etchable) relative to the first mask material 138 and the second mask material 402. In some embodiments, the first mask material 138 and the second mask material 402 comprise primarily silicon nitride (SiN) and/or silicon oxide (e.g., SiO₂) and are substantially free of carbon, and the third sacrificial material 902 comprises, consists essentially of, or consists of a carbon-based material, such as a spin-on-carbon (“SOC”) material conventionally used in hard masks. SOC material generally includes a carbon-containing polymer.

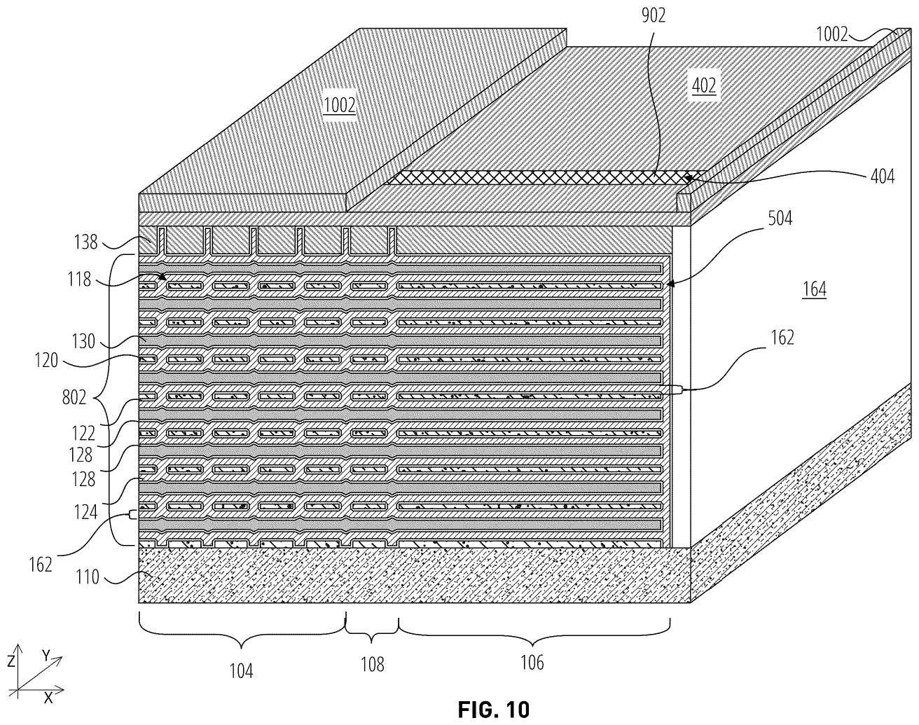

FIG. 10 illustrates a processing stage subsequent to the processing stage illustrated in FIG. 9. FIG. 10 is an isometric, cross-sectional illustration.

After filling the access line trenches 404 with the third sacrificial material 902, a resist material 1002 may be formed (e.g., deposited) above the second mask material 402 and patterned so that the array area 104 is covered by the resist material 1002 and at least the access line trench 404 area(s) in the staircase area 106 is (are) exposed. In embodiments including a transition area 108 between the array area 104 and the staircase area 106, the transition area 108 may provide a marginal area in which the edge of the resist material 1002 may be positioned. The dimensions (e.g., length in the X-axis direction) of the transition area 108, including the number of discrete regions 118 of semiconductor material 120 included in the transition area 108, may be selected to ensure that the resist material 1002 wholly covers the array area 104 and wholly uncovers all of the access line trench 404 area within the staircase area 106. Accordingly, though the figures illustrate the transition area 108 with a single discrete region 118 of semiconductor material 120 per tier, the disclosure is not so limited.

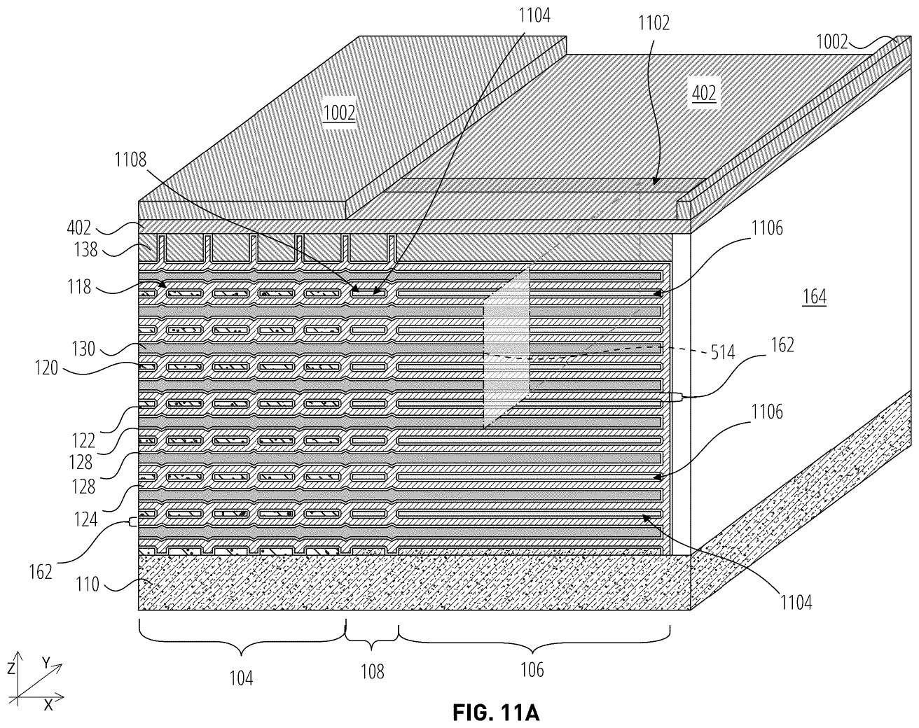

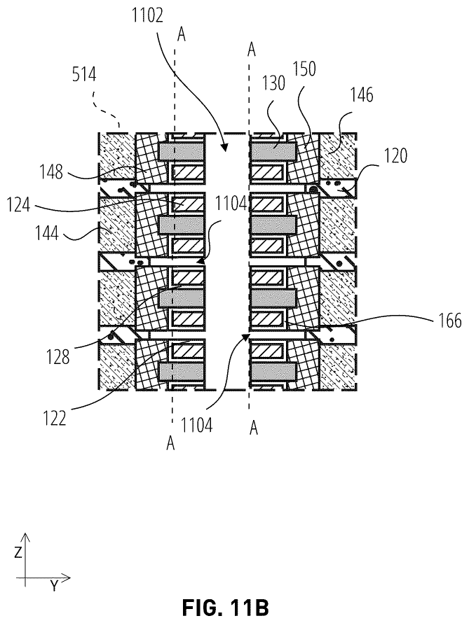

FIG. 11A and FIG. 11B illustrate a processing stage subsequent to the processing stage illustrated in FIG. 10. FIG. 11A is an isometric, cross-sectional illustration. FIG. 11B is an along-X-axis view of box 514 of FIG. 11A. The front side of the illustration of FIG. 11A equally illustrates an along-Y-axis view corresponding to either of section lines A-A of FIG. 11B. Though FIG. 11B is a cross-sectional view in the staircase area 106, it equally represents a cross-sectional view in the transition area 108.

After covering the array area 104 and exposing at least the access line trench 404 of the staircase area 106, the third sacrificial material 902 (FIG. 10) may be selectively removed (e.g., anisotropically etched) to partially-reopen the access line trench 404 (FIG. 10), forming partially-reopened access line trenches 1102. In embodiments in which the third sacrificial material 902 comprises a carbon-based material (e.g., SOC), an oxygen-based etchant chemistry (e.g., an oxygen-based plasma) may be used for the selective etching.

The third sacrificial material 902 may be removed from substantially only the staircase area 106 while remaining in the array area 104. Some or all of the third sacrificial material 902 from the transition area 108 may also be removed, depending upon whether the patterning of the resist material 1002 exposed part or all of the transition area 108. Removing the third sacrificial material 902 (FIG. 10) from the staircase area 106 and the exposed portion of any transition area 108 may expose sidewalls of the semiconductor material 120, as well as other materials of the intermediary stack structure 802 (FIG. 10) to the partially-reopened access line trenches 1102.

Via the partially-reopened access line trenches 1102, the semiconductor material 120 in the staircase area 106 and exposed portions of any transition area 108 may be selectively removed (e.g., etched) relative to insulative material(s) (e.g., such as the gate insulator regions 122, the outer insulative regions 128, and the intermediate insulative regions 130) and conductive material 126 (e.g., of the conductive regions 124). The selectively removal of semiconductor material 120 may recess the semiconductor material 120, leaving initial core voids 1104.

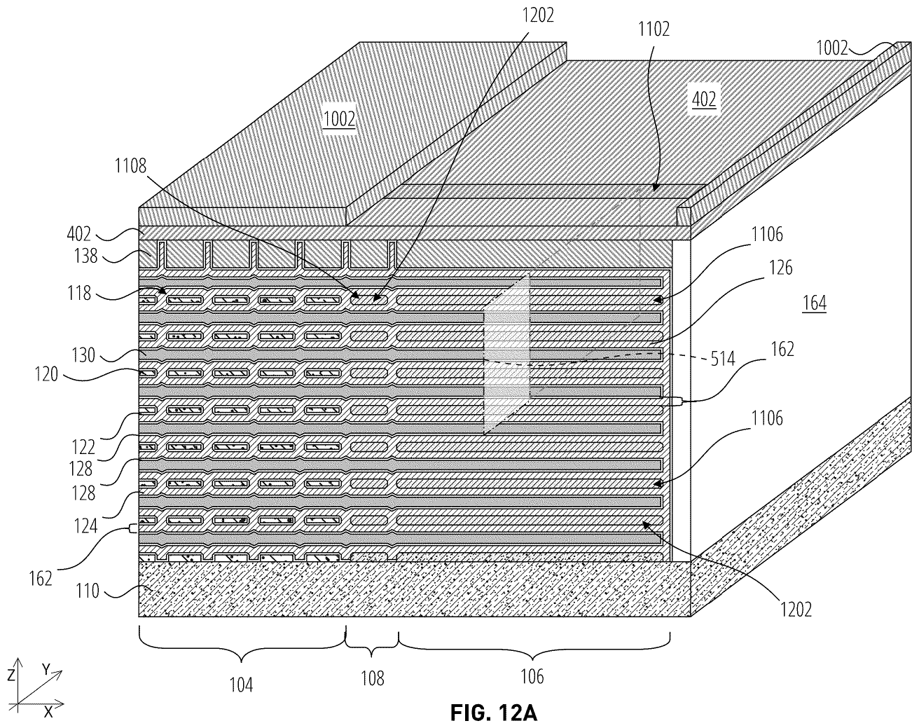

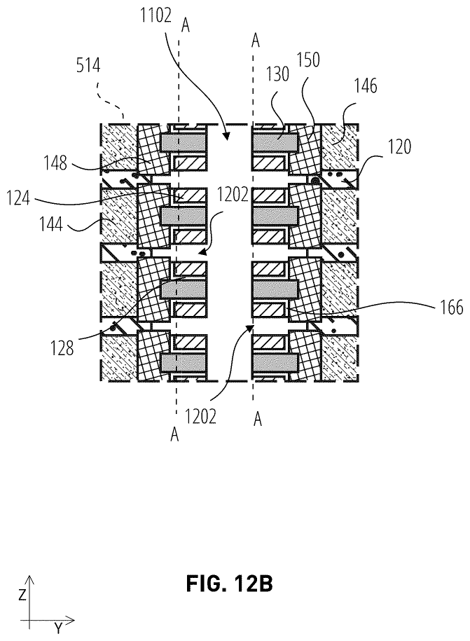

FIG. 12A and FIG. 12B illustrate a processing stage subsequent to the processing stage illustrated in FIG. 11A and FIG. 11B. FIG. 12A is an isometric, cross-sectional illustration. FIG. 12B is an along-X-axis view of box 514 of FIG. 12A. The front side of the illustration of FIG. 12A equally illustrates an along-Y-axis view corresponding to either of section lines A-A of FIG. 12B. Though FIG. 12B is a cross-sectional view in the staircase area 106, it equally represents a cross-sectional view in the transition area 108.

After removing (e.g., horizontally recessing) the semiconductor material 120 to form the initial core voids 1104 (FIG. 11A and FIG. 11B), the insulative material(s) of the gate insulator regions 122 may also be removed (e.g., etched), in whole or in part, via the partially-reopened access line trenches 1102 to form core voids 1202 that expose surfaces of the conductive material 126.

In embodiments in which the intermediate insulative regions 130 comprise an insulative material of the same, substantially the same, or similar composition as the insulative material(s) of the gate insulator regions 122, some portion of the intermediate insulative regions 130 may also be removed along with removing the gate insulator regions 122. In these embodiments, a majority of the intermediate insulative regions 130 may remain after removing the gate insulator regions 122, which may be due in part to the intermediate insulative regions 130 having a significantly greater volume of insulative material(s) than the gate insulator regions 122.

In embodiments in which the intermediate insulative regions 130 comprise, consist essentially of, or consist of an oxycarbide material (e.g., silicon oxycarbide) and the gate insulator regions 122 comprise, consist essentially of, or consist of a silicon oxide (e.g., SiO₂) that is substantially free of carbon, the removal of the gate insulator regions 122 may be a material-removal process that is selective relative to the intermediate insulative regions 130. For example, a hydrogen-fluoride (HF) etchant chemistry may be used to selectively etch the gate insulator regions 122 without substantially removing the intermediate insulative regions 130.

The removal of the semiconductor material 120 and the gate insulator regions 122 from the staircase area 106 forms elongate voids 1106 between upper and lower portions of the conductive material 126. In embodiments including the transition area 108, the removal of the semiconductor material 120 and the 122 from the transition area 108 also forms at least one discrete void 1108, per tier, between upper and lower portions of the conductive material 126.

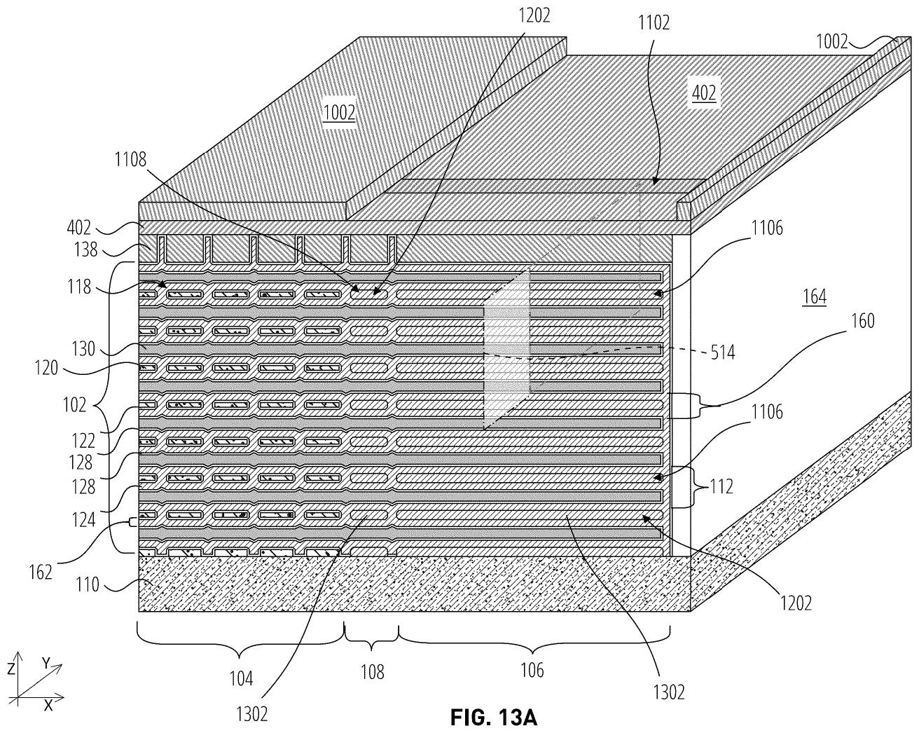

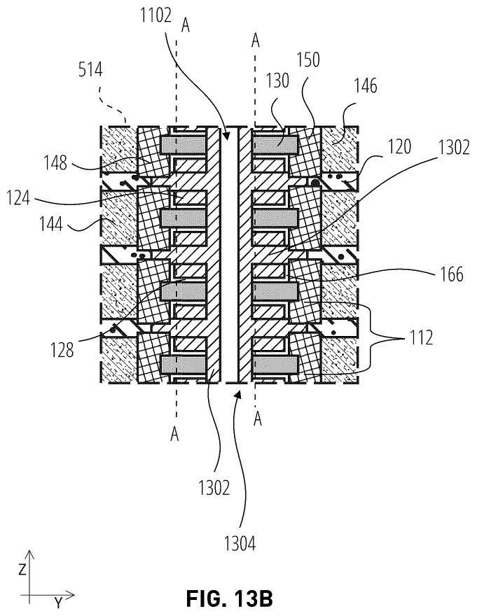

FIG. 13A and FIG. 13B illustrate a processing stage subsequent to the processing stage illustrated in FIG. 12A and FIG. 12B. FIG. 13A is an isometric, cross-sectional illustration. FIG. 13B is an along-X-axis view of box 514 of FIG. 13A. The front side of the illustration of FIG. 13A equally illustrates an along-Y-axis view corresponding to either of section lines A-A of FIG. 13B. Though FIG. 13B is a cross-sectional view in the staircase area 106, it equally represents a cross-sectional view in the transition area 108.

Via the partially-reopened access line trenches 1102, additional conductive material 1302 is formed (e.g., deposited, such as by CVD and/or ALD) in the core voids 1202 (e.g., in the elongate voids 1106 of the staircase area 106 and in the discrete voids 1108 of the transition area 108) to substantially fill the space vertically between the original upper and lower regions of the conductive material 126.

In some embodiments, the additional conductive material 1302 is of substantially the same composition as the conductive material 126. Therefore, the original conductive material 126 and the additional conductive material 1302 may be collectively referred to hereinafter and with regard to the microelectronic device structure 100 of FIG. 1A and FIG. 1B as the “conductive material” 126.

Forming the additional conductive material 1302 may form bridges—illustrated in bridge area 1304 of FIG. 13B—of the additional conductive material 1302 along the sidewalls of the partially-reopened access line trenches 1102, as illustrated in FIG. 13B. An anisotropic etch may be performed to remove the sidewalls of the additional conductive material 1302 that cross the intermediate insulative regions 130 to facilitate physical and electrical isolation of the conductive material 126 (including remnants of the additional conductive material 1302) of one conductive region 124 and one tier 112 relative to the neighboring conductive regions 124 of vertically neighboring tiers 112. By removing the bridge areas 1304, the additional conductive material 1302 may be isolated to the area between portions of the original conductive material 126. In some embodiments, the additional conductive material 1302 longitudinally (Y-axis direction) extends between vertically neighboring remnants 148 of the second sacrificial material 150.

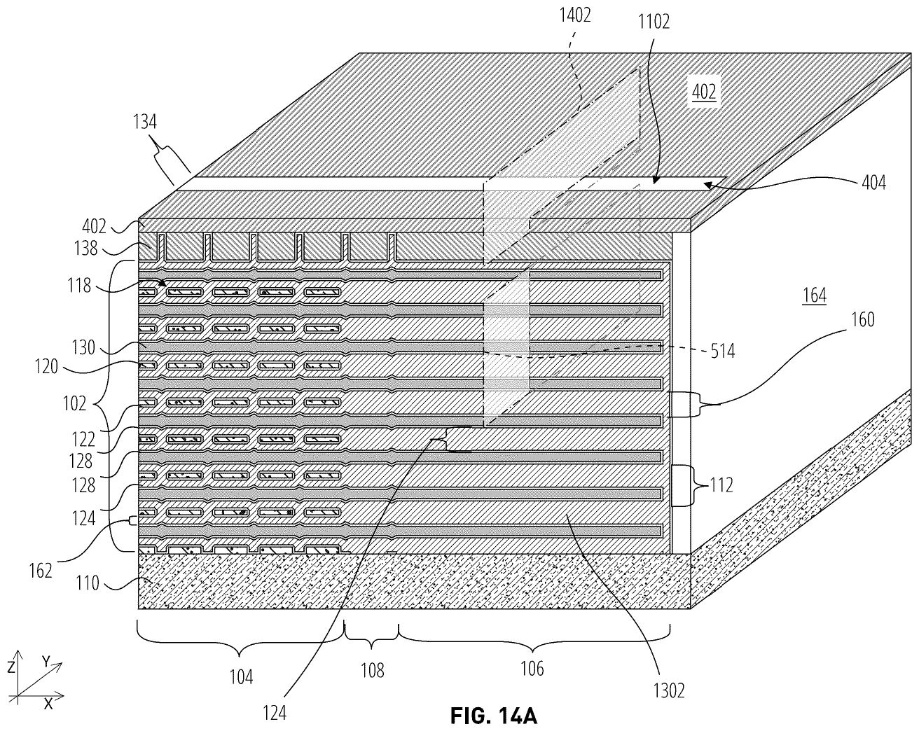

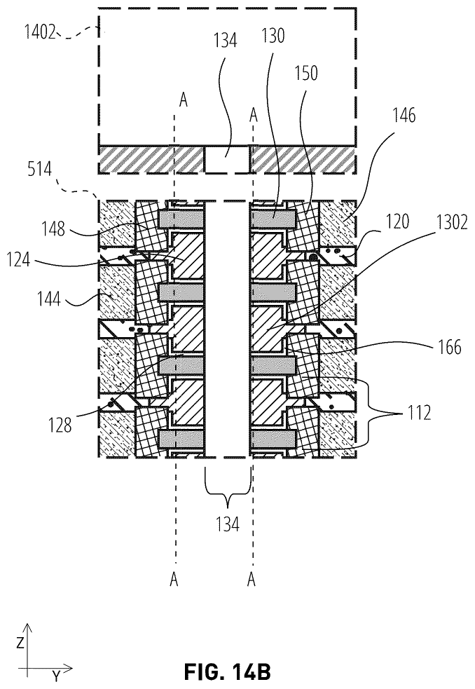

FIG. 14A and FIG. 14B illustrate a processing stage subsequent to the processing stage illustrated in FIG. 13A and FIG. 13B. FIG. 14A is an isometric, cross-sectional illustration. FIG. 14B is an along-X-axis view of box 514 and box 1402 of FIG. 14A. The front side of the illustration of FIG. 14A equally illustrates an along-Y-axis view corresponding to either of section lines A-A of FIG. 14B. Though FIG. 14B is a cross-sectional view in the staircase area 106, it equally represents a cross-sectional view in the transition area 108.

In embodiments in which the additional conductive material 1302 is of substantially the same composition as the original conductive material 126, forming the additional conductive material 1302 may result in the additional conductive material 1302 being indistinguishable from the original conductive material 126, as illustrated in FIG. 14A and FIG. 14B.

After forming the additional conductive material 1302 and isolating the conductive material 126 (including the additional conductive material 1302) to respective tiers 112, the interblock insulative structures 134 may be formed. For example, the resist material 1002 may be removed to expose the remainder of the area in which the access line trenches 404 were formed, and the remainder of the third sacrificial material 902 (FIG. 9) may be removed to wholly reopen the access line trenches 404. The insulative material(s) of the interblock insulative structures 134 may be formed (e.g., deposited) in the access line trenches 404 to form the interblock insulative structures 134, as illustrated in FIG. 14A.

After forming the additional conductive material 1302, the conductive region 124 of each tier 112 is substantially monolithic and uninterrupted by other material regions (e.g., between upper and lower outer insulative regions 128) in the staircase area 106 and the transition area 108, and the conductive region 124 of each tier 112 is also interrupted by the discrete regions 118 of semiconductor material 120 and the gate insulator regions 122 in the array area 104. In the array area 104, the conductive region 124 vertically and laterally surrounds the discrete regions 118 of semiconductor material 120, with the gate insulator regions 122 interposed between the conductive material 126 and the semiconductor material 120; and, in the staircase area 106 and, if included, the transition area 108, the conductive region 124 does not enclose any semiconductor material. Therefore, in the staircase area 106, and in the transition area 108 if included, the conductive region 124 exhibits the thickness 160 of conductive material 126 (e.g., from lowest surface of conductive material 126 to highest surface of conductive material 126 in the tier 112) that is significantly greater than the thickness 162 of conductive material 126 of, e.g., the portion of conductive material 126 that is above one of the discrete regions 118 of semiconductor material 120. In some embodiments, the thickness 160 of the conductive region 124 in the staircase area 106 (and in the transition area 108, if included) is at least twice (e.g., about three times) the thickness 162 of the conductive region 124 portion above the semiconductor material 120 in the array area 104.

The staircase area 106, and the transition area 108 if included, may be substantially free of semiconductor material (e.g., the semiconductor material 120), at least vertically above and below the intermediate insulative regions 130, as illustrated in FIG. 14B. In some embodiments, remnant portions of semiconductor material 120 remain in the staircase area 106, distal from the interblock insulative structure 134.

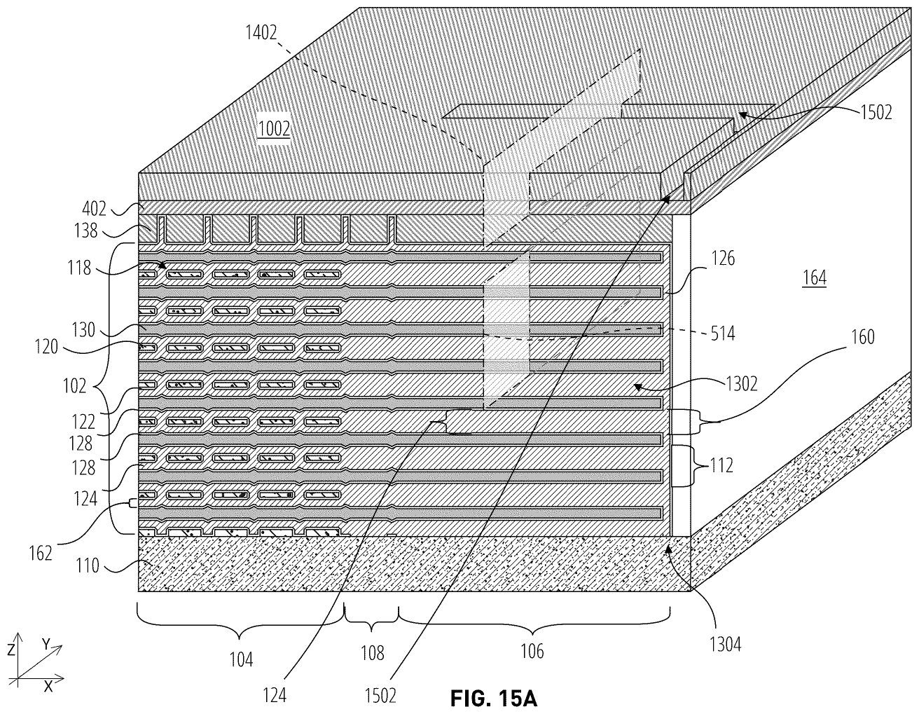

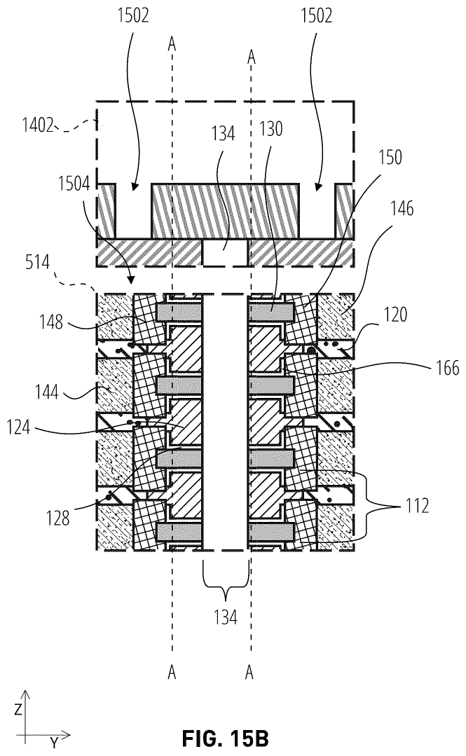

FIG. 15A and FIG. 15B illustrate a processing stage subsequent to the processing stage illustrated in FIG. 14A and FIG. 14B. FIG. 15A is an isometric, cross-sectional illustration. FIG. 15B is an along-X-axis view of box 514 and box 1402 of FIG. 15A. The front side of the illustration of FIG. 15A equally illustrates an along-Y-axis view corresponding to either of section lines A-A of FIG. 15B. Though FIG. 15B is a cross-sectional view in the staircase area 106, it equally represents a cross-sectional view in the transition area 108.

After forming the additional conductive material 1302 in the staircase area 106 and the transition area 108 (if any) to complete formation of the greater thickness 160 of the conductive region 124, some amount of conductive material 126 may remain along some vertical sides of the tiers 112, such as in the bridge area 1304 indicated in FIG. 15A, e.g., at lateral ends of the tiers 112. To physically and electrically isolate the conductive regions 124 of the tiers 112 of the stack structure 102 from one another, the bridge area 1304 may be etched to trim away the sidewall of the conductive material 126 and, in some embodiments, also the sidewall of insulative material of the outer insulative regions 128 in the bridge area 1304. Accordingly, the resist material 1002 may be formed and patterned to define an edge opening 1502 over the bridge area 1304, at least.

In some embodiments, concurrent with forming the edge opening 1502 over the bridge area 1304, additional edge openings 1502 are formed over distal-edge-of-block areas 1504, as illustrated in FIG. 15B, so as to define the distal sidewalls of a pair of neighboring blocks 132 (FIG. 1A) and separate laterally neighboring blocks 132 from one another.

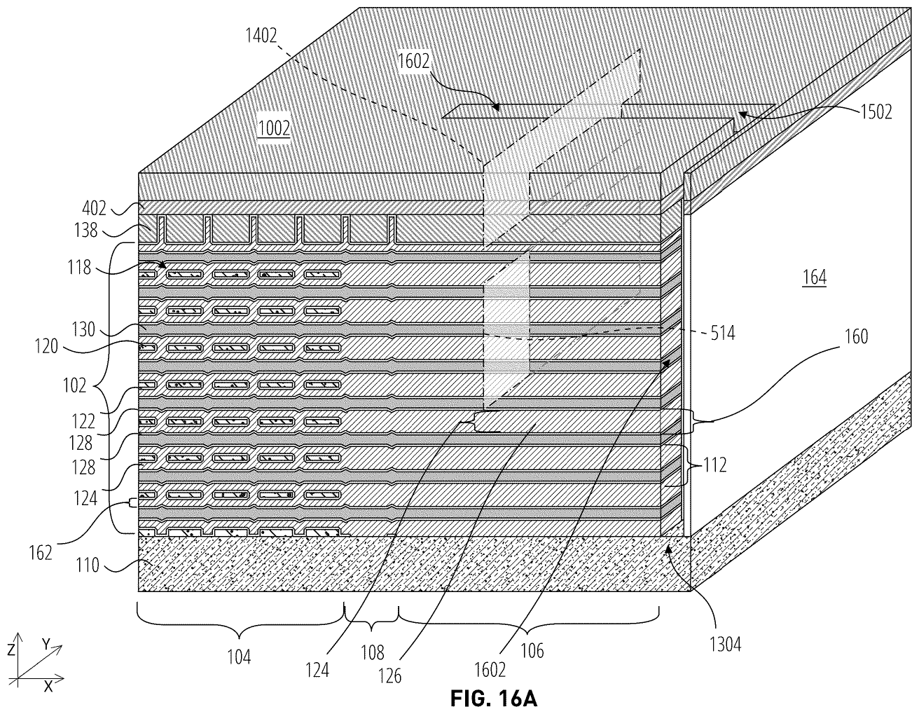

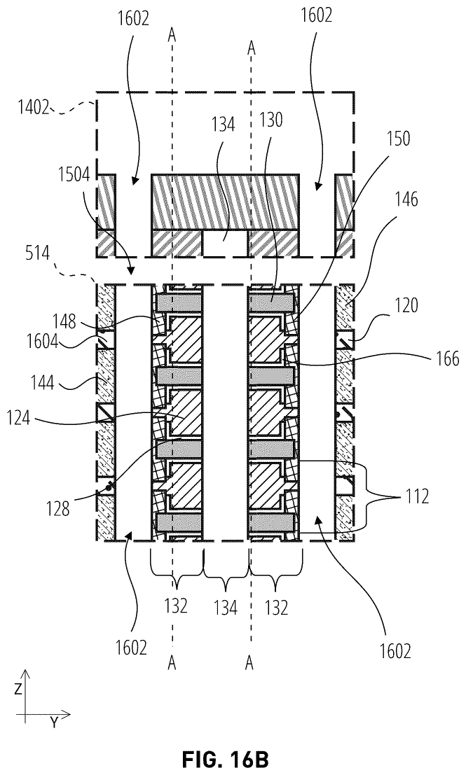

FIG. 16A and FIG. 16B illustrate a processing stage subsequent to the processing stage illustrated in FIG. 15A and FIG. 15B. FIG. 16A is an isometric, cross-sectional illustration. FIG. 16B is an along-X-axis view of box 514 and box 1402 of FIG. 16A. The front side of the illustration of FIG. 16A equally illustrates an along-Y-axis view corresponding to either of section lines A-A of FIG. 16B. Though FIG. 16B is a cross-sectional view in the staircase area 106, it equally represents a cross-sectional view in the transition area 108.

Edge trenches 1602 may be formed (e.g., etched) through the stack structure 102 in the bridge area 1304, as illustrated in FIG. 16A, and through the distal-edge-of-block areas 1504, as illustrated in FIG. 16B. The edge trenches 1602 may extend to or into the base structure 110. After edge trimming, each conductive region 124 may be physically and electrically isolated to its respective tier 112, and the blocks (FIG. 16B) may be defined. Each block 132 may have a sidewall (e.g., parallel to the X-Z plane) along one of the X-axis direction edge trenches 1602, an opposite sidewall (e.g., parallel to the X-Z plane) along the interblock insulative structure 134, and an endwall (e.g., parallel to the Y-Z plane) along the Y-axis direction edge trench 1602 (FIG. 16A), near the former bridge area 1304.

Though the rear edge opening 1502 and the edge trench 1602 illustrated in FIG. 16A extend substantially through only the staircase area 106 of the stack structure 102, the disclosure is not so limited. In some embodiments, edge openings 1502 and edge trenches 1602 parallel to the X-axis extend a full width of the array area 104 and, if present, the transition area 108 so as to wholly isolate the conductive regions 124 of the tiers 112 from their longitudinal and vertical neighbors. In other embodiments, previous processing stages have already completed—and/or subsequent processing stages are performed to complete—the physical separation of the conductive material 126, and therefore the conductive regions 124, in the array area 104 and the transition area 108, if present.

In some embodiments, the edge trim in the distal-edge-of-block areas 1504 leaves remnants 148 of the second sacrificial material 150 adjacent the distal sidewall of the (e.g., each) block 132, as illustrated in FIG. 16B. These remnants 148 of second sacrificial material 150 may remain in the microelectronic device structure 100 (FIG. 1A) after completion of fabrication. In other embodiments, the remnants 148 may be removed and replaced with other material (e.g., insulative material(s)).

In some embodiments, one or more areas that are longitudinally adjacent one of the edge trenches 1602 but that are not configured for inclusion in one of the blocks 132 include remnants 144 of the first sacrificial material 146 and remnants 1604 of the semiconductor material 120 (e.g., silicon (Si)). Though FIG. 16B illustrates both the areas to both the left- and right-hand sides of the pair of blocks 132 as including remnants 144 of first sacrificial material 146 and remnants 1604 of semiconductor material 120, the disclosure is not so limited. In some embodiments, one or both of these areas may also have been processed to form an additional block 132, such as with materials and a structure substantially matching the illustrated blocks 132, e.g., mirrored about the edge trenches 1602. In such embodiments, the longitudinally distal edges of the staircase area 106 (FIG. 16A) neighbor an area with remnants 144 of the first sacrificial material 146 and/or remnants 1604 of the semiconductor material 120. Nonetheless, within the staircase area 106 itself, the materials of the stack structure 102 (FIG. 1A) may be substantially free of the semiconductor material 120 and, in some embodiments, the first sacrificial material 146.

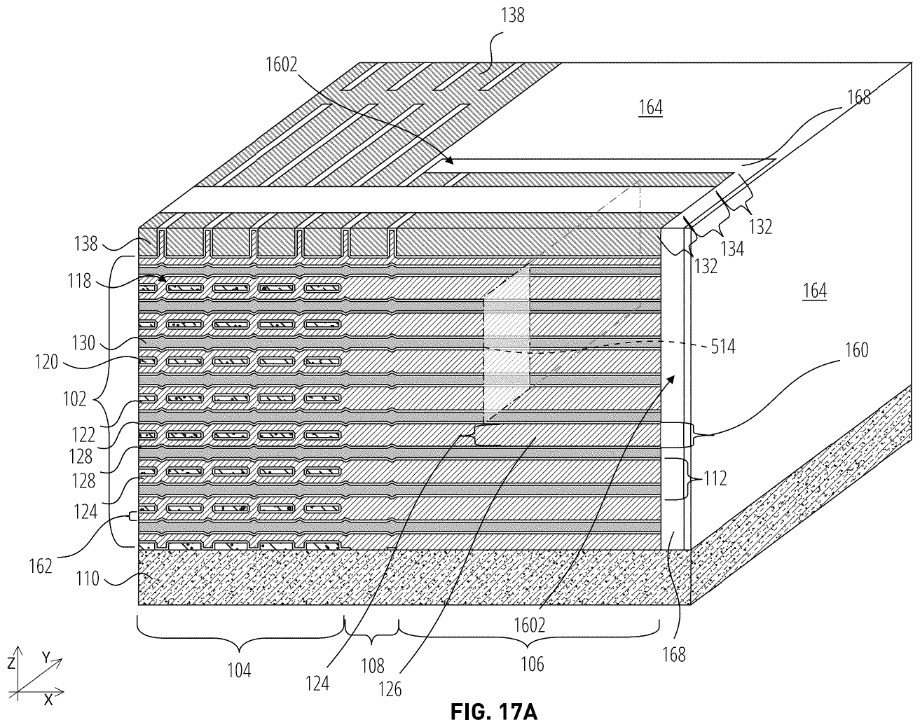

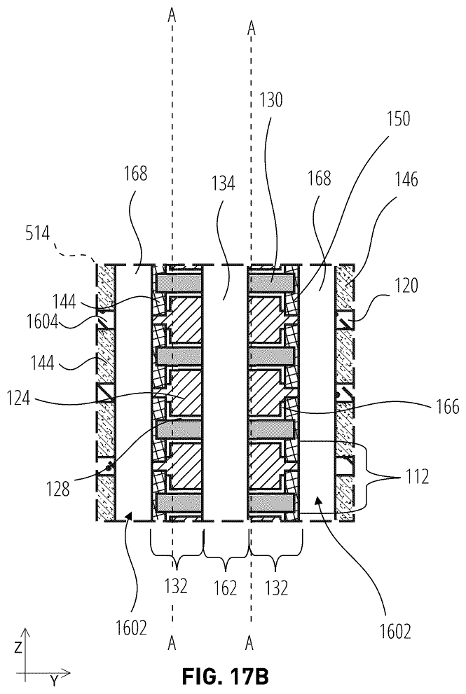

FIG. 17A and FIG. 17B illustrate a processing stage subsequent to the processing stage illustrated in FIG. 16A and FIG. 16B. FIG. 17A is an isometric, cross-sectional illustration. FIG. 17B is an along-X-axis view of box 514 of FIG. 17A. The front side of the illustration of FIG. 17A equally illustrates an along-Y-axis view corresponding to either of section lines A-A of FIG. 17B. Though FIG. 17B is a cross-sectional view in the staircase area 106, it equally represents a cross-sectional view in the transition area 108.

After isolating the respective conductive regions 124 of the tiers 112 of the stack structure 102 in each block 132, one or more insulative material(s) may be formed (e.g., deposited) in the edge trenches 1602 to form edge insulative structures 168. In some embodiments, the insulative material(s) of the edge insulative structures 168 have substantially a same composition as the insulative material 164, the interblock insulative structure 134, and/or other neighboring insulative material(s) regions.

Though FIG. 17A illustrates the resist material 1002 (FIG. 16A) used for forming the edge trenches 1602 as having been removed, the disclosure is not so limited. In some embodiments, the resist material 1002 remains in place through the stage illustrated in FIG. 17A and FIG. 17B.

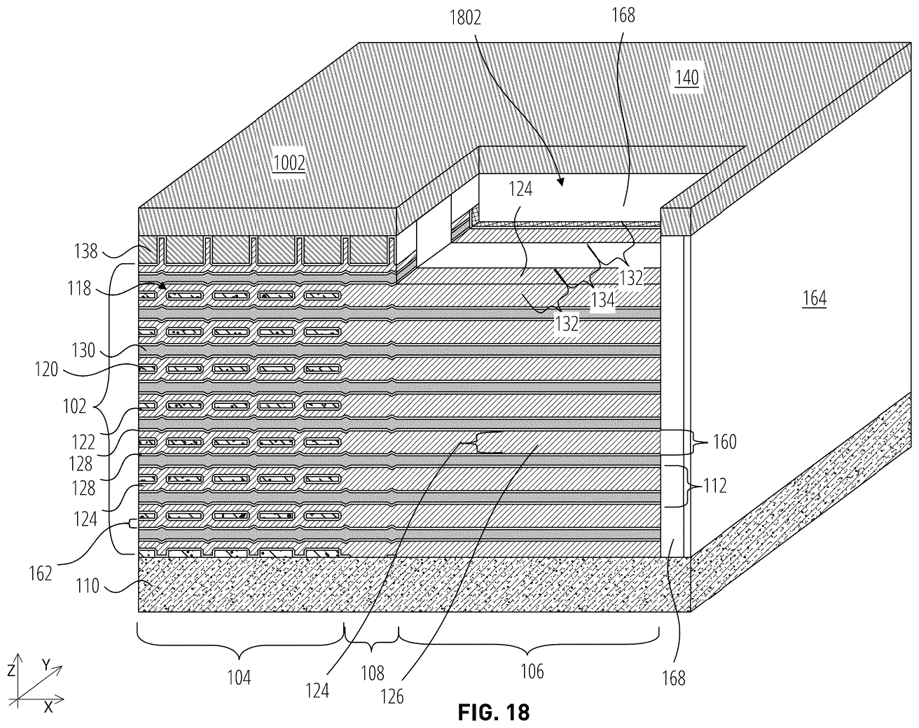

FIG. 18 illustrates a processing stage subsequent to the processing stage illustrated in FIG. 17A and FIG. 17B. FIG. 18 is an isometric, cross-sectional illustration. The front side of the illustration of FIG. 18 equally illustrates an along-Y-axis view corresponding to the front surface of the rearward block 132 of the pair of blocks 132 illustrated in FIG. 18.

The resist material 1002 may be re-formed above the stack structure 102, including above the first mask material 138 if still present, and patterned (e.g., etched) in the staircase area 106 of one or more of the blocks 132. In some embodiments, the patterning may form an opening 1802 that exposes an upper surface of the conductive region 124 of the uppermost tier 112 at which a step 114 (FIG. 1A) is to be formed.

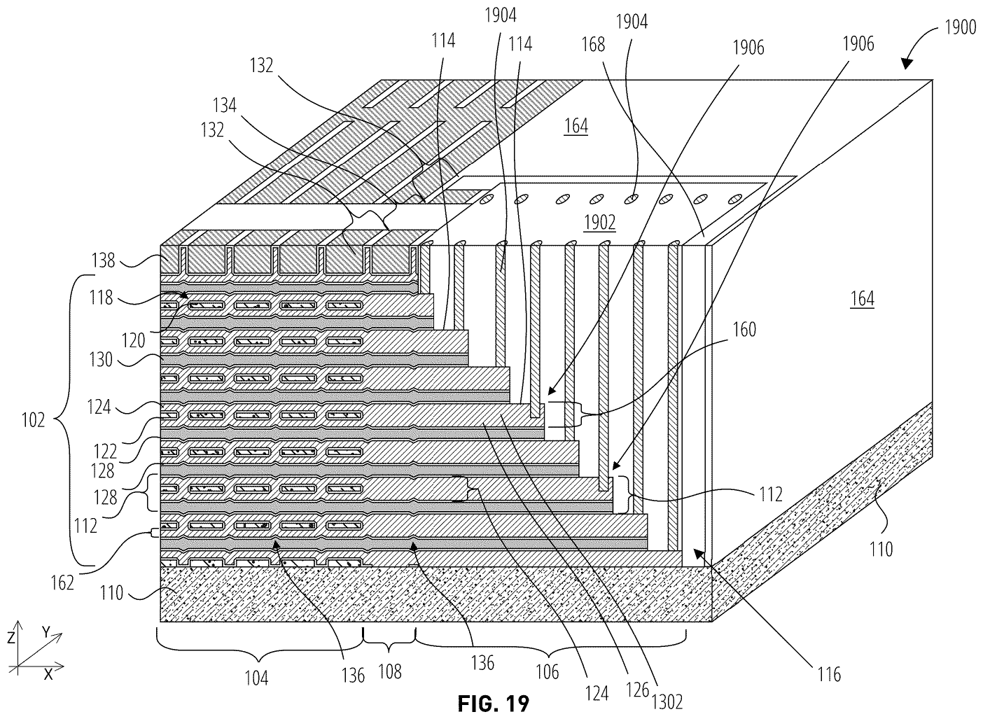

FIG. 19 illustrates a processing stage subsequent to the processing stage illustrated in FIG. 18. FIG. 19 is an isometric, cross-sectional illustration. The front side of the illustration of FIG. 19 equally illustrates an along-Y-axis view corresponding to the front surface of the rearward block 132 of the pair of blocks 132 illustrated in FIG. 19.

A sequence of mask or resist formations, trimmings (e.g., etchings), and stack structure 102 etching stages may be performed to form the staircase structure 116 with steps 114 at the various elevations of the conductive regions 124 of the tiers 112 in the stack structure 102. For example, the area of the lowest step 114 may be exposed in the staircase area 106, while other areas of the staircase area 106 are covered, and the stack structure 102 may be etched the height of one step 114. Then, the area of both the lowest and second lowest step 114 may be exposed in the staircase area 106, while the other areas of the staircase area 106 are covered, and the stack structure 102 may be etched the height of one step 114, extending the etched opening to the depth of two steps 114 in the first step 114 area and to the depth of one step 114 in the second step 114 area. This process may be continued for each subsequent step 114 until the staircase structure 116 is completed.

Due to the previous removal of the semiconductor material 120 from the staircase area 106, the material-removal acts of forming the staircase structure 116 may involve substantially only removing conductive material (e.g., the conductive material 126 and the additional conductive material 1302 of the conductive regions 124) and insulative material(s) (e.g., the outer insulative regions 128 and the intermediate insulative regions 130) in the staircase area 106, not semiconductor material 120. Accordingly, etching the stack structure 102 in the staircase area 106 may be relatively less complex in etching through interleaved conductive and insulative materials, than if etching through interleaved conductive, insulative, and semiconductor materials.

In addition, the relatively greater thickness 160 of the conductive region 124 in the staircase area 106 may provide a relatively greater processing margin for etching the stack structure 102 to form the steps 114 of the staircase structure 116 at target conductive regions 124 in the staircase area 106, than if, for example, the conductive region 124 retained the lesser thickness 162 of the above-semiconductor-portion of conductive material 126 as in the array area 104. Accordingly, the risk of an unintentional over-etching failure (e.g., whole removal of the conductive region 124 in the area of a step 114 being formed) may be significantly less with the relatively greater thickness 160 of the conductive region 124 in the staircase area 106 than if the conductive region 124 of the staircase area 106 retained the surrounding-semiconductor structure as in the array area 104.

In a resulting microelectronic device structure 1900 (which may include the stack structure 102 of the microelectronic device structure 100 of FIG. 1A), in each block 132, the conductive region 124 of each tier 112 may be continuous in its conductive material 126 from one end of the tier 112 (e.g., the end providing one of the steps 114) to an opposite end. Accordingly, the step 114 area of the conductive region 124 may be in electrical communication with areas of the same conductive region 124 in the array area 104.

After forming the staircase structures 116 with the steps 114 at the various tier 112 elevations of the conductive regions 124 of the stack structure 102, one or more insulative material(s) may be formed in the opening above the staircase structure 116 to form an insulative fill structure 1902. The insulative fill material(s) of the insulative fill structure 1902 may comprise the same or different insulative material(s) as in other insulative regions of the microelectronic device structure 100 (FIG. 1A), such as the edge insulative structures 168, the insulative material 164, and/or the interblock insulative structures 134.

Contact openings may be formed (e.g., etched) through the insulative fill structure 1902 to the steps 114 at the various tier 112 elevations (e.g., depths). One or more conductive material(s) may be formed in the contact openings to form conductive contact structures 1904 extending to target steps 114. Accordingly, the conductive region 124 of each tier 112 may function as an “access line” (or otherwise referred to as a “word line”) in electrical communication with the corresponding access devices comprising the conductive region 124 in the array area 104.

Should any contact opening be inadvertently formed (e.g., etched) to a greater depth than the tread of a target step 114, such as in over-etch areas 1906, there may be a lower likelihood of the resulting conductive contact structure 1904 extending wholly through the conductive region 124 that provides the step 114, due to the relatively greater thickness 160 of the conductive region 124 in the staircase area 106, than if the conductive region 124 retained the around-semiconductor structure as in the array area 104.

FIG. 19 illustrates a microelectronic device structure 1900 that includes the microelectronic device structure 100 of FIG. 1A, and further includes the insulative fill structure 1902 and conductive contact structures 1904. Before or after forming the insulative fill structure 1902 and the conductive contact structures 1904, the resist material 1002 (FIG. 18) may be removed. Accordingly, though FIG. 1A illustrates the microelectronic device structure 100 as including an upper material 140 (which may represent the resist material 1002 of FIG. 18), in some embodiments, the final microelectronic device structure 100 and devices and systems including such structure (e.g., the microelectronic device structure 100, the microelectronic device structure 1900) do not include the upper material 140.

Accordingly, disclosed is a method of forming a microelectronic device. The method comprises forming a stack structure of tiers. The tiers individually comprise a semiconductor material, an insulative material, and a conductive material. The tiers further individually comprise, in a first area of the stack structure, discrete regions of the semiconductor material and, in a second area of the stack structure, a laterally elongate region of the semiconductor material. The conductive material vertically and laterally surrounds the discrete regions and the laterally elongate region of the semiconductor material. The insulative material is vertically and laterally interposed between the conductive material and the semiconductor material of the discrete regions and the laterally elongate region. A trench is formed through the second area of the stack structure. Via the trench, the semiconductor material and the insulative material are horizontally recessed in the second area to form recesses vertically and laterally surrounded by the conductive material. Additional conductive material is formed in the recesses to form conductive regions comprising the conductive material and the additional conductive material. The conductive regions individually extending through the first area and the second area. The conductive regions individually have a greater thickness in the second area than in the first area.

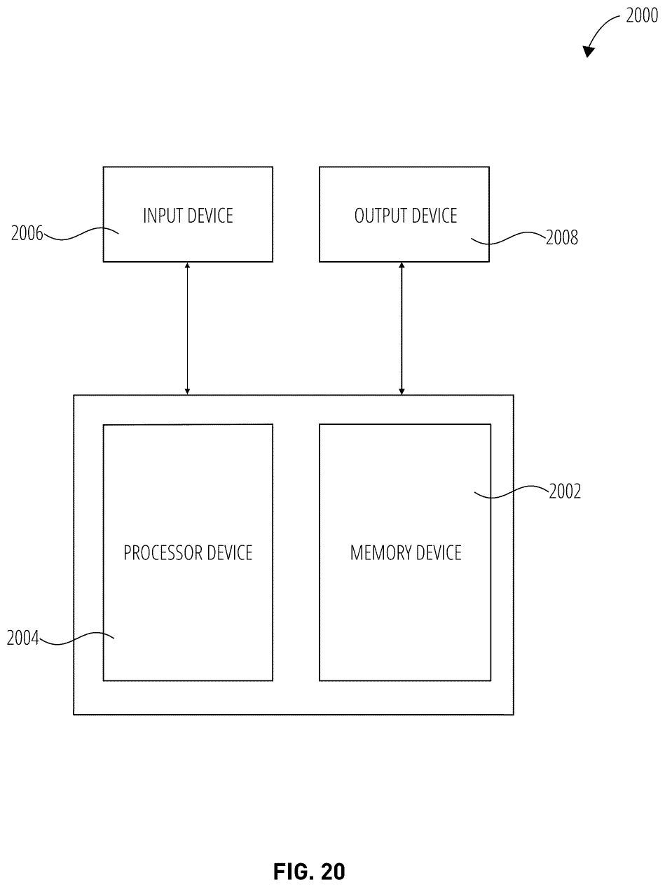

Microelectronic devices including microelectronic device structures—such as the microelectronic device structure 100 of FIG. 1A, the structure(s) of FIG. 1B, and/or the microelectronic device structure 1900 of FIG. 19—may be used in embodiments of electronic systems of the disclosure. For example, FIG. 20 is a block diagram of an electronic system 2000, in accordance with embodiments of the disclosure. The electronic system 2000 may comprise, for example, a computer or computer hardware component, a server or other networking hardware component, a cellular telephone, a digital camera, a personal digital assistant (PDA), a portable media (e.g., music) player, a Wi-Fi or cellular-enabled tablet (e.g., an iPAD® or SURFACE® tablet, an electronic book, a navigation device), etc. The electronic system 2000 includes at least one memory device 2002. The memory device 2002 may include, for example, an embodiment of a microelectronic device and/or structure previously described herein (e.g., the microelectronic device structure 100 of FIG. 1A, the structure(s) of FIG. 1B, and/or the microelectronic device structure 1900 of FIG. 19), with structures formed according to methods of embodiments previously described herein.

The electronic system 2000 may further include at least one electronic signal processor device 2004 (often referred to as a “microprocessor”). The processor device 2004 may, optionally, include an embodiment of a microelectronic device and/or a microelectronic device structure previously described herein (e.g., one or more of the microelectronic device structure 100 of FIG. 1A, the structure(s) of FIG. 1B, and/or the microelectronic device structure 1900 of FIG. 19). The electronic system 2000 may further include one or more input devices 2006 for inputting information into the electronic system 2000 by a user, such as, for example, a mouse or other pointing device, a keyboard, a touchpad, a button, or a control panel. The electronic system 2000 may further include one or more output devices 2008 for outputting information (e.g., visual or audio output) to a user such as, for example, a monitor, a display, a printer, an audio output jack, a speaker, etc. In some embodiments, the input device 2006 and the output device 2008 comprise a single touchscreen device that can be used both to input information into the electronic system 2000 and to output visual information to a user. The input device 2006 and the output device 2008 may communicate electrically with one or more of the memory device 2002 and the electronic signal processor device 2004.

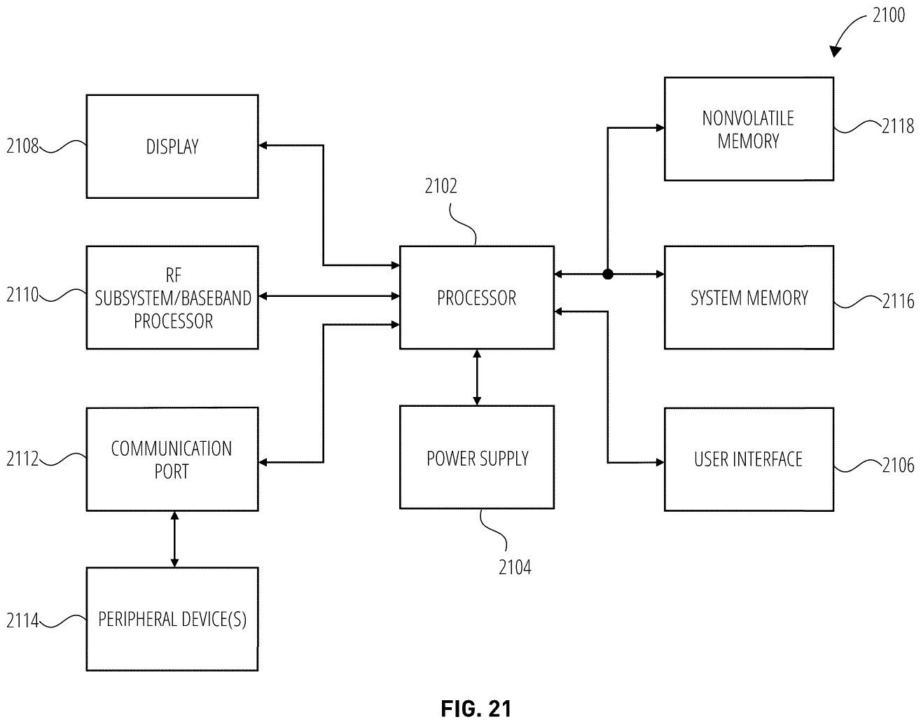

With reference to FIG. 21, shown is a block diagram of a processor-based system 2100. The processor-based system 2100 may include various microelectronic devices (e.g., device(s) including the microelectronic device structure 100 of FIG. 1A, the structure(s) of FIG. 1B, and/or the microelectronic device structure 1900 of FIG. 19) manufactured in accordance with embodiments of the present disclosure. The processor-based system 2100 may be any of a variety of types, such as a computer, a pager, a cellular phone, a personal organizer, a control circuit, or another electronic device. The processor-based system 2100 may include one or more processors 2102, such as a microprocessor, to control the processing of system functions and requests in the processor-based system 2100. The processor 2102 and other subcomponents of the processor-based system 2100 may include microelectronic devices (e.g., device(s) including the microelectronic device structure 100 of FIG. 1A, the structure(s) of FIG. 1B, and/or the microelectronic device structure 1900 of FIG. 19) manufactured in accordance with embodiments of the present disclosure.

The processor-based system 2100 may include a power supply 2104 in operable communication with the processor 2102. For example, if the processor-based system 2100 is a portable system, the power supply 2104 may include one or more of a fuel cell, a power scavenging device, permanent batteries, replaceable batteries, and/or rechargeable batteries. The power supply 2104 may also include an AC adapter; therefore, the processor-based system 2100 may be plugged into a wall outlet, for example. The power supply 2104 may also include a DC adapter such that the processor-based system 2100 may be plugged into a vehicle cigarette lighter or a vehicle power port, for example.

Various other devices may be coupled to the processor 2102 depending on the functions that the processor-based system 2100 performs. For example, a user interface 2106 may be coupled to the processor 2102. The user interface 2106 may include one or more input devices, such as buttons, switches, a keyboard, a light pen, a mouse, a digitizer and stylus, a touch screen, a voice recognition system, a microphone, or a combination thereof. A display 2108 may also be coupled to the processor 2102. The display 2108 may include an LCD display, an SED display, a CRT display, a DLP display, a plasma display, an OLED display, an LED display, a three-dimensional projection, an audio display, or a combination thereof. Furthermore, an RF subsystem/baseband processor 2110 may also be coupled to the processor 2102. The RF subsystem/baseband processor 2110 may include an antenna that is coupled to an RF receiver and to an RF transmitter. A communication port 2112, or more than one communication port 2112, may also be coupled to the processor 2102. The communication port 2112 may be adapted to be coupled to one or more peripheral devices 2114 (e.g., a modem, a printer, a computer, a scanner, a camera) and/or to a network (e.g., a local area network (LAN), a remote area network, an intranet, or the Internet).

The processor 2102 may control the processor-based system 2100 by implementing software programs stored in the memory (e.g., system memory 2116). The software programs may include an operating system, database software, drafting software, word processing software, media editing software, and/or media-playing software, for example. The memory (e.g., the system memory 2116) is operably coupled to the processor 2102 to store and facilitate execution of various programs. For example, the processor 2102 may be coupled to system memory 2116, which may include one or more of spin torque transfer magnetic random-access memory (STT-MRAM), magnetic random access memory (MRAM), dynamic random access memory (DRAM), static random access memory (SRAM), racetrack memory, and/or other known memory types. The system memory 2116 may include volatile memory, nonvolatile memory, or a combination thereof. The system memory 2116 is typically large so it can store dynamically loaded applications and data. In some embodiments, the system memory 2116 includes semiconductor devices and structures (e.g., the microelectronic device structure 100 of FIG. 1A, the structure(s) of FIG. 1B, and/or the microelectronic device structure 1900 of FIG. 19) described above, or a combination thereof.

The processor 2102 may also be coupled to nonvolatile memory 2118, which is not to suggest that system memory 2116 is necessarily volatile. The nonvolatile memory 2118 may include one or more of STT-MRAM, MRAM, read-only memory (ROM) (e.g., EPROM, resistive read-only memory (RROM)), and Flash memory to be used in conjunction with the system memory 2116. The size of the nonvolatile memory 2118 is typically selected to be just large enough to store any necessary operating system, application programs, and fixed data. Additionally, the nonvolatile memory 2118 may include a high-capacity memory (e.g., disk drive memory, such as a hybrid-drive including resistive memory or other types of nonvolatile solid-state memory, for example). The nonvolatile memory 2118 may include microelectronic devices and structures (e.g., the microelectronic device structure 100 of FIG. 1A, the structure(s) of FIG. 1B, and/or the microelectronic device structure 1900 of FIG. 19) described above, or a combination thereof.

Accordingly, disclosed is an electronic system comprising a microelectronic device, at least one processor, and at least one peripheral device. The at least one processor is in operable communication with the microelectronic device. The at least one peripheral device is in operable communication with the at least one processor. The at least one microelectronic device comprises a stack structure. The stack structure comprises a vertical stack of tiers comprising conductive regions. The conductive regions individually extend through an array area and into a staircase area horizontally neighboring the array area. The array area comprises a vertical stack of horizontally-oriented access devices that individually comprise a channel region and a gate electrode. The channel region comprises a discrete region of semiconductor material. The gate electrode comprises conductive material of the conductive region of a respective one of the tiers. The gate electrode vertically and laterally surrounds the channel region. The staircase area comprises a staircase structure having steps at ends of the conductive regions. Portions of the tiers within the staircase area are substantially free of the semiconductor material.

While the disclosed structures, apparatus (e.g., devices), systems, and methods are susceptible to various modifications and alternative forms in implementation thereof, specific embodiments have been shown by way of example in the drawings and have been described in detail herein. However, the disclosure is not intended to be limited to the particular forms disclosed. Rather, the disclosure encompasses all modifications, combinations, equivalents, variations, and alternatives falling within the scope of the disclosure as defined by the following appended claims and their legal equivalents.

What is claimed is:

1. A microelectronic device, comprising:
a stack structure comprising tiers individually extending through an array area comprising at least one access device and into a staircase area horizontally neighboring the array area and comprising a staircase structure having steps at ends of the tiers, at least some of the tiers individually comprising:
a conductive region comprising conductive material extending through the array area and into the staircase area, a thickness of the conductive material greater in the staircase area than in the array area;
insulative regions in the array area and in the staircase area; and
discrete regions of semiconductor material in the array area, the staircase area substantially free of the semiconductor material.

2. The microelectronic device of claim 1, further comprising insulative structures extending completely through the stack structure, the insulative structures dividing the stack structure into blocks.

3. The microelectronic device of claim 2, wherein a neighboring pair of the blocks substantially mirror one another across one of the insulative structures.

4. The microelectronic device of claim 2, wherein at least one of the blocks comprises, in at least some of the tiers, a nitride material along a sidewall distal from the one of the insulative structures.

5. The microelectronic device of claim 1, wherein the insulative regions in the array area comprise gate insulator regions interposed between the semiconductor material and the conductive material, the insulative regions each vertically and laterally surrounding a respective one of the discrete regions of the semiconductor material.

6. The microelectronic device of claim 5, wherein the insulative regions in the array area further comprise intermediate insulative structures vertically between the conductive regions.

7. The microelectronic device of claim 6, wherein the intermediate insulative structures extend through the array area and into the staircase area.

8. The microelectronic device of claim 5, wherein the insulative regions in the array area further comprise outer insulative regions vertically interposed between the conductive material and each vertically neighboring intermediate insulative structure of the intermediate insulative structures.

9. The microelectronic device of claim 8, wherein the outer insulative regions extend through the array area and into the staircase area.

10. The microelectronic device of claim 1, wherein an upper boundary of the conductive region defines:
in the array area, a row of divots; and
in the staircase area, a substantially planar surface free of divots.

11. The microelectronic device of claim 1, further comprising a transition area horizontally between the array area and the staircase area, wherein:
the conductive region extends through the transition area;
the transition area is substantially free of the semiconductor material; and
an upper boundary of the conductive region has a divot where the transition area adjoins the staircase area.

12. The microelectronic device of claim 1, wherein:
the at least one access devices comprises multiple access devices;
the array area has a vertical stack of the access devices within boundaries thereof; and
the access devices are each horizontally oriented.

13. A method of forming a microelectronic device, the method comprising:
forming a stack structure of tiers individually comprising a semiconductor material, an insulative material, and a conductive material, the tiers further individually comprising:
in a first area of the stack structure, discrete regions of the semiconductor material;
in a second area of the stack structure, a laterally elongate region of the semiconductor material;
the conductive material vertically and laterally surrounding the discrete regions and the laterally elongate region of the semiconductor material; and
the insulative material vertically and laterally interposed between the conductive material and the semiconductor material of the discrete regions and the laterally elongate region;
forming a trench through the second area of the stack structure;
via the trench, horizontally recessing the semiconductor material and the insulative material in the second area to form recesses vertically and laterally surrounded by the conductive material; and
forming additional conductive material in the recesses to form conductive regions comprising the conductive material and the additional conductive material and individually extending through the first area and the second area, the conductive regions individually having a greater thickness in the second area than in the first area.

14. The method of claim 13, wherein forming the stack structure comprises:
forming a precursor stack structure in the first area and the second area, the precursor stack structure comprising a vertically alternating sequence of the semiconductor material and a first sacrificial material;
forming insulative trench structures extending through the precursor stack structure in the first area to form the discrete regions of the semiconductor material;
forming an initial trench through the precursor stack structure in the first area and the second area;
via the initial trench, horizontally recessing the first sacrificial material and the insulative trench structures relative to the semiconductor material to form first voids;
forming a second sacrificial material on the semiconductor material in the first voids;
forming an additional insulative material on the second sacrificial material in the first voids to form intermediate insulator regions;
via the initial trench, horizontally recessing the second sacrificial material to form second voids;
forming the insulative material on the semiconductor material in the second voids and forming the conductive material on the insulative material; and
forming a third sacrificial material to substantially fill the initial trench in at least the first area.

15. The method of claim 14, wherein:
forming the third sacrificial material to substantially fill the initial trench in at least the first area comprises forming the third sacrificial material to substantially fill the initial trench in the first area and in the second area; and
forming the trench through the second area of the stack structure comprises partially reopening the initial trench.

16. The method of claim 13, further comprising, after forming the additional conductive material:
patterning a portion of the stack structure within the second area to form a staircase structure comprising steps at upper boundaries of the conductive regions; and
maintaining substantially all the semiconductor material while patterning the portion of the stack structure within the second area to form the staircase structure.

17. The method of claim 13, wherein horizontally recessing the semiconductor material and the insulative material in the second area to form the recesses comprises forming laterally elongate recesses in the second area.

18. The method of claim 13, further comprising, before forming the additional conductive material, horizontally recessing the semiconductor material and the insulative material in a third area horizontally between the first area and the second area to form additional recesses, the recesses in the second area being longer than the additional recesses in the third area.

19. The method of claim 13, further comprising removing portions of the conductive material along lateral sidewalls to isolate the conductive material within respective ones of the tiers of the stack structure.

20. An electronic system, comprising:
a microelectronic device comprising:
a stack structure comprising a vertical stack of tiers comprising conductive regions, the conductive regions individually extending through an array area and into a staircase area horizontally neighboring the array area,
the array area comprising a vertical stack of horizontally-oriented access devices individually comprising:
a channel region comprising a discrete region of semiconductor material; and
a gate electrode comprising conductive material of the conductive region of a respective one of the tiers, the gate electrode vertically and laterally surrounding the channel region; and
the staircase area comprising a staircase structure having steps at ends of the conductive regions, portions of the tiers within the staircase area substantially free of the semiconductor material;
at least one processor in operable communication with the microelectronic device; and
at least one peripheral device in operable communication with the at least one processor.
